(19) United States
(12) Patent Application Publication
(10) Pub. No.: US 2026/0255751 A1
(43) Pub. Date: Aug. 27, 2026

(54) Transparent Display Panel and Display Apparatus

(71) Applicant: BOE Technology Group Co., Ltd., Beijing (CN)

(72) Inventors: Dapeng XUE, Beijing (CN); Zhiqiang XU, Beijing (CN)

(21) Appl. No.: 18/730,296

(22) PCT Filed: Mar. 24, 2023
(86) PCT No.: PCT/CN2023/083823

§ 371 Date: Jul. 18, 2024

(51) Int. Cl. H10H 29/41; H10H 29/49

(52) U.S. Cl. CPC H10H 29/41; H10H 29/49

(57) ABSTRACT

A transparent display panel and a display apparatus are disclosed. The transparent display panel includes a substrate, and a plurality of repeating units arranged in an array on the substrate. A repeating unit comprises a non-transmissive region and a plurality of transmissive regions, wherein adjacent transmissive regions are spaced apart by the non-transmissive region; a transmissive region includes a hollowed-out region and a transition region, the transition region is located between the non-transmissive region and the hollowed-out region, and at least one insulation layer in the hollowed-out region is provided in a hollowed-out structure; the non-transmissive region includes at least one pixel unit and N sets of first traces extending in a first direction and M sets of second traces extending in a second direction electrically connected to the pixel unit, the first direction intersects the second direction, and both N and M are positive integers.

### CROSS-REFERENCE TO RELATED APPLICATIONS

The present application is a U.S. National Phase Entry of International Application PCT/CN2023/083823 having an international filing date of Mar. 24, 2023 and entitled “Transparent Display Panel and Display Apparatus”, the contents of which are incorporated herein by reference in their entireties.

### TECHNICAL FIELD

The present disclosure relates to, but is not limited to, the field of display technology, in particular to a transparent display panel and a display apparatus.

### BACKGROUND

Transparent display technology has a broad application prospect as it can present not only images in a display screen but also physical objects behind the display screen. The transparent display technology has been widely applied in display windows, transparent TV, vehicle-mounted technology, virtual reality (VR), augmented reality (AR) and other fields.

### SUMMARY

The following is a summary of subject matter described herein in detail. This summary is not intended to limit the protection scope of claims.

An embodiment of the present disclosure provides a transparent display panel and a display apparatus.

In one aspect, embodiments of the present disclosure provide a transparent display panel including: a substrate;
a plurality of repeating units arranged in an array on the substrate, a repeating unit includes a non-transmissive region and a plurality of transmissive regions, adjacent transmissive regions are spaced apart by a non-transmissive region; the transmissive region includes a hollowed-out region and a transition region, wherein the transition region is located between the non-transmissive region and the hollowed-out region, and at least one insulation layer in the hollowed-out region is provided in a hollowed-out structure;
a non-transmissive region includes at least one pixel unit and N sets of first traces extending in a first direction and M sets of second traces extending in a second direction electrically connected to the at least one pixel unit, the first direction and the second direction intersect, and both N and M are positive integers.

In some exemplary implementation modes, the transition region has a size of 0 microns to 10 microns in a direction from the non-transmissive region to an adjacent hollowed-out region.

In some exemplary implementation modes, the transition region has a size of 8 microns in a direction from the non-transmissive region to an adjacent hollowed-out region.

In some exemplary implementation modes, the transparent display panel includes at least one conductive layer and at least one insulation layer disposed on the substrate, and one or more insulation layers located in the hollowed-out region are provided in a hollowed-out structure.

In some exemplary implementation modes, the transparent display panel further includes a semiconductor layer disposed on the substrate, the conductive layer includes a first conductive layer to a fourth conductive layer, and the at least one insulation layer includes a first insulation layer to a seventh insulation layer;
in a direction perpendicular to the substrate, the first conductive layer to the fourth conductive layer are sequentially arranged on a side of the semiconductor layer away from the substrate, the first insulation layer is located between the semiconductor layer and the first conductive layer, the second insulation layer is located between the first conductive layer and the second conductive layer, the third insulation layer is located between the second conductive layer and the third conductive layer, the fourth insulation layer and the fifth insulation layer are located between the third conductive layer and the fourth conductive layer, and the sixth insulation layer and the seventh insulation layer are sequentially arranged on a side of the fourth conductive layer away from the substrate; and
at least one of the first insulation layer to the seventh insulation layer located in the hollowed-out region is provided in a hollowed-out structure. In some exemplary implementation modes, a buffer layer is further provided between the substrate and the semiconductor layer in the direction perpendicular to the substrate, and the buffer layer located in the hollowed-out region may be provided in a hollowed-out structure.

In some exemplary implementation modes, a transmittance of the transition region is

$$\frac{b}{a} {E}_{0} {e}^{i ( kr - ( φ 1 - φ 2 ) )} ,$$

a transmittance of hollowed-out region is E₀e^{ikr}, the value of k is 2 π/λ, λ is a wave length of light wave, r is a size of the insulation layer located in the transition region in the direction perpendicular to the substrate, E0 is an amplitude of light wave, φ1 is an optical delay of the transition region, φ2 is the optical delay of the hollowed-out region, a is a first transmittance reference value, and b is a second transmittance reference value.

In some exemplary implementation modes, the optical delay φ1 of the transition region is a product of a size and a refractive index of a film layer located in the transition region in the direction perpendicular to the substrate.

In some exemplary implementation modes, a refractive index of the transition region has a value range of 1.2 to 1.6, a value of r of the transition region has a value range of 3 microns to 7 microns, and a wavelength of light has a value range of 500 nanometers to 560 nanometers.

In some exemplary implementation modes, the refractive index of the transition region is 1.4, the value of r of the transition region has a value range of 5 to 6 microns, and the wavelength of light is 532 nanometers.

In some exemplary implementation modes, a refractive index of the hollowed-out region is 1 and a value of r of the hollowed-out region is 0 micron.

In some exemplary implementation modes, a transmittance of the non-transmissive region is 0.

In some exemplary implementation modes, at least one set of first traces includes: a plurality of first signal lines; at least one set of second traces includes a plurality of third signal lines and at least one fourth signal line, an orthographic projection of the at least one fourth signal line on the substrate covers an orthographic projection of at least two third signal lines on the substrate.

In some exemplary implementation modes, a size of the at least one fourth signal line in the first direction is larger than a size of the at least two third signal lines in the first direction.

In some exemplary implementation modes, N and M are both 1, a set of first traces includes a plurality of first signal lines, and a set of second traces includes a plurality of third signal lines and at least one fourth signal line; the at least one fourth signal line includes a first power supply line and a second power supply line; an orthographic projection of at least one of the first power supply line and the second power supply line on the substrate covers an orthographic projection of the plurality of third signal lines on the substrate.

In some exemplary implementation modes, N is 1 and M is 2, a set of first traces includes a plurality of first signal lines, two sets of second traces include a plurality of third signal lines and at least two fourth signal lines, and one set of second traces includes some of the third signal lines and at least one of the fourth signal lines; the at least two fourth signal lines include a first power supply line and a second power supply line; an orthographic projection of at least one of the first power supply line and the second power supply line on the substrate covers an orthographic projection of the plurality of third signal lines on the substrate.

In some exemplary implementation modes, the at least one pixel unit includes: a plurality of sub-pixels emitting light of different colors, a plurality of sub-pixels in a same pixel unit are located at two sides of one of the fourth signal lines in the first direction, and at least some of the sub-pixels are located between two fourth signal lines.

In some exemplary implementation modes, the plurality of first signal lines of the set of first traces includes a scan line, a light emitting control line, a first power connection line, and a second power connection line, the first power connection line is electrically connected to the first power supply line, and the second power connection line is electrically connected to the second power supply line.

In some exemplary implementation modes, the plurality of third signal lines includes at least a plurality of data lines electrically connected to the at least one pixel unit.

In some exemplary implementation modes, the at least one pixel unit includes a plurality of sub-pixels, and the transmissive region includes a spacing region between the plurality of sub-pixels and between the sub-pixels and the first trace or the second trace in a same pixel unit.

In another aspect, embodiments of the present disclosure provide a display apparatus, including the transparent display panel described in any of the above embodiments.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is an equivalent circuit diagram of a pixel circuit according to at least one embodiment of the present disclosure.

FIG. 2 is an operating timing diagram of the pixel circuit shown in FIG. 1.

FIG. 3 is a schematic partial view of a transparent display panel according to at least one embodiment of the present disclosure.

FIG. 4 is a schematic diagram of a repeating unit of a transparent display panel according to at least one embodiment of the present disclosure.

FIG. 5 is a schematic partial sectional view of a transparent display panel according to at least one embodiment of the present disclosure.

FIG. 6A is a schematic diagram of a semiconductor layer of a repeating unit according to at least one embodiment of the present disclosure.

FIG. 6B is a schematic view of a first conductive layer of a repeating unit according to at least one embodiment of the present disclosure.

FIG. 6C is a schematic view of a second conductive layer of a repeating unit according to at least one embodiment of the present disclosure.

FIG. 6D is a schematic view of a third insulation layer of a repeating unit according to at least one embodiment of the present disclosure.

FIG. 6E is a schematic diagram of a third conductive layer of a repeating unit according to at least one embodiment of the present disclosure.

FIG. 6F is a schematic diagram of a fifth insulation layer of a repeating unit according to at least one embodiment of the present disclosure.

FIG. 6G is a schematic view of a fourth conductive layer of a repeating unit according to at least one embodiment of the present disclosure.

FIG. 6H is a schematic view of a seventh insulation layer of a repeating unit according to at least one embodiment of the present disclosure.

FIG. 7 is another schematic partial view of a transparent display panel according to at least one embodiment of the present disclosure.

FIG. 8 is a schematic diagram of a repeating unit of a transparent display panel according to at least one embodiment of the present disclosure.

FIG. 9 is a flowchart of a method for evaluating quality of a picture according to at least one embodiment of the present disclosure.

FIG. 10 is an example diagram of a display effect of a picture in which a width of a transition region is 18 microns.

FIG. 11 is an example diagram of a display effect of a picture in which a width of a transition region is 8 microns according to at least one embodiment of the present disclosure.

FIG. 12 is an example diagram of a display effect of a picture in which a width of a transition region is 0 microns according to at least one embodiment of the present disclosure.

FIG. 13 is a schematic diagram of a relationship between a width of a transition region and an image quality according to at least one embodiment of the present disclosure.

FIG. 14 is a schematic diagram of a relationship between a diffraction intensity in a second direction Y and a width of a transition region according to at least one embodiment of the present disclosure.

FIG. 15 is a schematic diagram of a relationship between a diffraction intensity in a first direction X and a width of a transition region according to at least one embodiment of the present disclosure.

FIG. 16 is a schematic diagram of diffraction.

FIG. 17 is a schematic diagram of a relationship between an optical delay and a diffraction intensity according to at least one embodiment of the present disclosure.

FIG. 18 is a schematic diagram of a display apparatus according to at least one embodiment of the present disclosure.

### DETAILED DESCRIPTION

The embodiments of the present disclosure will be described below with reference to the drawings in detail. Implementation modes may be implemented in multiple different forms. Those of ordinary skills in the art may easily understand such a fact that implementation modes and contents may be transformed into one or more forms without departing from the purpose and scope of the present disclosure. Therefore, the present disclosure should not be explained as being limited to the contents recorded in the following implementation modes only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, an implementation mode of the present disclosure is not always limited to the size, and the shape and size of each component in the drawings do not reflect an actual scale. In addition, the accompanying drawings schematically illustrate ideal examples, and an implementation mode of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “multiple” may include two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate based on directions according to which the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand meanings of the aforementioned terms in the present disclosure according to situations.

In the specification, “electrical connection” includes connection between composition elements through an element with a certain electrical action. An “element with a certain electrical action” is not particularly limited as long as electrical signals between the connected constituent elements may be sent and received. Examples of the “element with the certain electrical action” not only include electrodes and wirings, but also include switching elements such as transistors, resistors, inductors, capacitors, other elements with one or more functions, etc.

In the specification, a transistor refers to an element that at least includes three terminals, i.e., a gate electrode, a drain electrode, and a source electrode. The transistor has a channel region between the drain electrode (drain electrode terminal, drain area, or drain) and the source electrode (source electrode terminal, source area, or source), and a current can flow through the drain electrode, the channel region and the source electrode. In the present disclosure, the channel region refers to a region through which a current mainly flows.

In this specification, for distinguishing the two electrodes except the gate electrode of the transistor, one electrode is called a first electrode, and the other electrode is called a second electrode. The first electrode may be the source electrode or the drain electrode, and the second electrode may be the drain electrode or the source electrode. In addition, a gate electrode of a transistor may be called a control electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

In the specification, a “film” and a “layer” are interchangeable. For example, a “conductive layer” may be replaced with a “conductive thin film” sometimes. Similarly, an “insulation film” may be replaced with an “insulation layer” sometimes.

In the specification, “about” and “substantially” refer to that a boundary is not defined strictly and a case within a process and measurement error range is allowed. In this specification, “substantially the same” may be a case where numerical values differ by less than 10%.

In the present disclosure, “thickness” and “height” refer to a vertical distance between a surface of a side of a film layer away from the substrate and a surface of a side close to the substrate.

Micro Light Emitting Diode (Micro-LED) technology, that is, LED miniaturization and matrixing technology, refers to a high-density and micro-size LED array integrated on a single chip. For example, each pixel of LED display screen can be addressed and individually driven to light up, and distances between pixel points can be reduced from millimeter to micrometer. Micro-LED display device has the characteristics of self-luminescence display, which has advantages of all-solid-state, long life, high brightness, low power consumption, small size, ultra-high resolution, and can be applied to extreme environments such as high temperature or radiation. Moreover, Micro LED not only has high efficiency and long life, its materials are not easy to be affected by the environment, so its performance is relatively stable, and it can also avoid afterimage phenomenon. Micro LED can be widely used in display fields such as display screen, backlight and lighting, and is known as the next generation display technology. Mini Diode (Mini-LED) and Micro Light Emitting Diode (Micro-LED) can be called MLED. MLED has the characteristics of high brightness and small light-emitting area, which has obvious advantages in the field of transparent display. Transparent display is widely used in display windows, transparent televisions, vehicles, VR glasses and other fields. At present, transmittance of LED transparent display products on the market is <70% and transmittance of products above 55 inches is <40%, so the overall transmittance is low. Therefore, how to improve the display transmittance and display clarity of MLED, and how to reduce occurrence of diffraction, is an urgent problem to be solved.

In some implementation modes, the transparent display panel includes transmissive regions and non-transmissive regions. Herein, the transmissive region and the non-transmissive region may be arranged alternately. If an area of part of the transmissive regions is too small and the distribution thereof is periodic, based on the principle of small-hole diffraction, a diffraction phenomenon will occur, and the smaller the sizes of the transmissive regions, the more obvious the diffraction phenomenon is. In the related technology, without changing a wiring design, with an increase of resolution (PPI, Pixels Per Inch) of a transparent display panel, the area of each transmissive region decreases, and strong diffraction occurs when ambient light passes through the transparent display panel, which leads to obvious ghosting when a picture presented by the transparent display panel are viewed, and reduces a display quality of the transparent display panel.

An embodiment provides a transparent display panel including a substrate and a plurality of repeating units arranged in an array on the substrate. A repeating unit includes a non-transmissive region and a plurality of transmissive regions, adjacent transmissive regions are spaced apart by the non-transmissive region. A transmissive region includes a hollowed-out region and a transition region, the transition region is located between the non-transmissive region and the hollowed-out region, and at least one insulation layer in the hollowed-out region is provided in a hollowed-out structure. The non-transmissive region includes: at least one pixel unit and N sets of first traces extending in a first direction and M sets of second traces extending in a second direction and electrically connected to the at least one pixel unit. The first direction intersects the second direction, for example, the first direction may be perpendicular to the second direction. N and M are positive integers.

In some examples, the transition region has a size of 0 microns to 10 microns in a direction from the non-transmissive region to an adjacent hollowed-out region.

In some examples, the transition region has a size of 8 microns in a direction from the non-transmissive region to an adjacent hollowed-out region. In an exemplary implementation mode of the present disclosure, the size of the transition region may be 0 to 8 microns in a direction from the non-transmissive region to an adjacent hollowed-out region. In embodiments of the present disclosure, an area of the hollowed-out region can be increased by reducing an area of the transition region covering the substrate, so as to improve a picture display quality and a sharpness.

In some examples, the transparent display panel includes at least one conductive layer and at least one insulation layer disposed on the substrate, and one or more insulation layers in the hollowed-out region are provided in hollowed-out structures.

In some examples, the transparent display panel may include a semiconductor layer, a first insulation layer, a first conductive layer, a second insulation layer, a second conductive layer, a third insulation layer, a third conductive layer, a fourth insulation layer, a fifth insulation layer, a fourth conductive layer, a sixth insulation layer, and a seventh insulation layer that are sequentially disposed on the substrate. At least one of the first insulation layer to the seventh insulation layer in the hollowed-out region is provided in a hollowed-out structure.

In some examples, a buffer layer is further provided between the substrate and the semiconductor layer in a direction perpendicular to the substrate, and the buffer layer located in the hollowed-out region may be provided in a hollowed-out structure.

In some examples, a transmittance of the transition region is

$$\frac{b}{a} {E}_{0} {e}^{i ( kr - ( φ 1 - φ 2 ) )} ,$$

a transmittance of hollowed-out region is E₀e^{ikr}, a value of k is 2 π/λ, λ is a wave length of light wave, r is a size of the insulation layer located in the transition region in the direction perpendicular to the substrate, E0 is an amplitude of light wave, φ1 is an optical delay of the transition region, φ2 is an optical delay of the hollowed-out region, a is a first transmittance reference value, and b is a second transmittance reference value.

In some examples, the optical delay φ1 of the transition region is a product of a size and a refractive index of a film layer located in the transition region in the direction perpendicular to the substrate.

In some examples, a refractive index of the transition region has a value range of 1.2 to 1.6, a value of r of the transition region has a value range of 3 microns to 7 microns, and the wavelength of light has a value range of 500 nanometers to 560 nanometers.

In some examples, the refractive index of the transition region is 1.4, the value of r of the transition region has a value range of 5 to 6 microns, and the wavelength of light is 532 nanometers.

In some examples, a refractive index of the hollowed-out region is 1 and the value of r of the hollowed-out region is 0 micron.

In some examples, the transmittance of the non-transmissive region is 0.

In an exemplary implementation mode, at least one set of first traces includes: a plurality of first signal lines, at least one set of second traces includes a plurality of third signal lines and at least one fourth signal line, an orthographic projection of the at least one fourth signal line on the substrate covers an orthographic projection of at least two third signal lines on the substrate.

In an exemplary implementation mode, a size of the at least one fourth signal line in the first direction is larger than a size of the at least two third signal lines in the first direction.

In some examples, both N and M are 1, a set of first traces includes a plurality of first signal lines, and a set of second traces includes a plurality of third signal lines and at least one fourth signal line. An orthographic projection of the at least one fourth signal line on the substrate covers an orthographic projection of at least two third signal lines on the substrate. In this example, the plurality of signal lines within each set of traces adopt in an aggregation design.

In an exemplary implementation mode, N is 1 and M is 2, a set of first traces includes a plurality of first signal lines, two sets of second traces include a plurality of third signal lines and at least two fourth signal lines, and a set of second traces includes some of the third signal lines and at least one fourth signal line. The at least two fourth signal lines include a first power supply line and a second power supply line, and an orthographic projection of at least one of the first power supply line and the second power supply line on the substrate covers an orthographic projection of the plurality of third signal lines on the substrate.

In an exemplary implementation mode, the at least one pixel unit includes: a plurality of sub-pixels emitting light of different colors, a plurality of sub-pixels in a same pixel unit are located at two sides of one of the fourth signal lines in the first direction, and at least some of the sub-pixels are located between two fourth signal lines.

In the present disclosure, using a superimposition design for two structures means that orthographic projections of the two structures overlap and that more than 90% of an orthographic projection of one of the structures may fall within an orthographic projection of the other structure. Aggregation design means that a plurality of signal lines are arranged in a centralized manner, for example, a spacing between two adjacent signal lines of the plurality of signal lines arranged in a centralized manner is less than twice of a line width of any one of the two signal lines. A region between adjacent signal lines located in a same film layer and using the aggregation design may be ignored and not be counted in the transmissive region. For example, the spacing between adjacent signal lines located in the same film layer and using the aggregation design may be about 3 microns to 5 microns.

In some examples, a non-transmissive region is a region where pixel units or signal traces, etc., for displaying images are present and background light on a back side of the transparent display panel cannot be transmitted or background light transmittance is small. A transmissive region is a region where pixel units or signal traces, etc., for displaying images are not present and background light on the back side of the transparent display panel can be transmitted or background light transmittance is large. The transmissive region of the present disclosure does not include a region between adjacent signal lines using an aggregation design, for example, if the spacing between two adjacent signal lines exceeds at least five times of a line width of any one of the two lines, a region between the two adjacent signal lines constitutes the transmissive region.

In the present disclosure, structure A extends in a direction B means that structure A may include a main body portion and a secondary portion connected to the main body portion, the main body portion is substantially in a shape of a strip extending in a direction, the secondary portion is in any shape, the main body portion counts for at least 60% of the structure A. The main body portion extends in the direction B, and a size of the main body portion extending in the direction B is larger than that of the secondary portion extending in another direction. In following description, “a structure A extends along a direction B” means that the main body portion of the structure A extends along the direction B.

In an exemplary implementation mode, using the superimposition design of signal traces in the transparent display panel, can achieve increased transmissive region, reduced diffraction, and improved display sharpness while ensuring the transmittance of the transparent display panel, thereby improving the transmittance and display quality of the transparent display panel.

In some exemplary embodiments, a pixel unit may include three sub-pixels. The three sub-pixels may be a red sub-pixel, a green sub-pixel, and a blue sub-pixel respectively. However, the embodiment is not limited thereto. In some examples, one pixel unit may include four sub-pixels, and the four sub-pixels are a red sub-pixel, a green sub-pixel, a blue sub-pixel, and a white sub-pixel respectively. In some examples, a shape of a sub-pixel may be a rectangle, a rhombus, a pentagon, or a hexagon. When a pixel unit includes three sub-pixels, the three sub-pixels may be spaced in a certain direction sequentially, or the three sub-pixels may be arranged in a zigzag pattern. When a pixel unit includes four sub-pixels, the four sub-pixels may be spaced in a certain direction sequentially or arranged in an array. However, the embodiment is not limited thereto.

In some examples, each sub-pixel may include: a pixel circuit and a light emitting element connected to the pixel circuit. An orthographic projection of the light emitting element of the sub-pixel on the substrate may overlap with an orthographic projection of the pixel circuit electrically connected to the light emitting element on the substrate. This example can increase the area of the transmissive region and improve transmittance by using a superimposition design for the light emitting element and the pixel circuit.

In some examples, the pixel circuit may include a plurality of transistors and at least one capacitor. For example, the pixel circuit may be in a 3T1C structure, a 7T1C structure, a 5T1C structure, an 8T1C structure, or an 8T2C structure, etc., wherein T in the above circuit structure refers to a thin film transistor, C refers to a capacitor, the number in front of T represents the number of thin film transistors in the circuit, and the number in front of C represents the number of capacitors in the circuit.

In some examples, the light emitting element may be an element with a light emitting area no larger than 1×10⁵ um², such as a micro light emitting diode (Micro-LED), or a mini diode (Mini-LED), or an organic light emitting diode (OLED), or Quantum dot Light Emitting Diode (QLED).

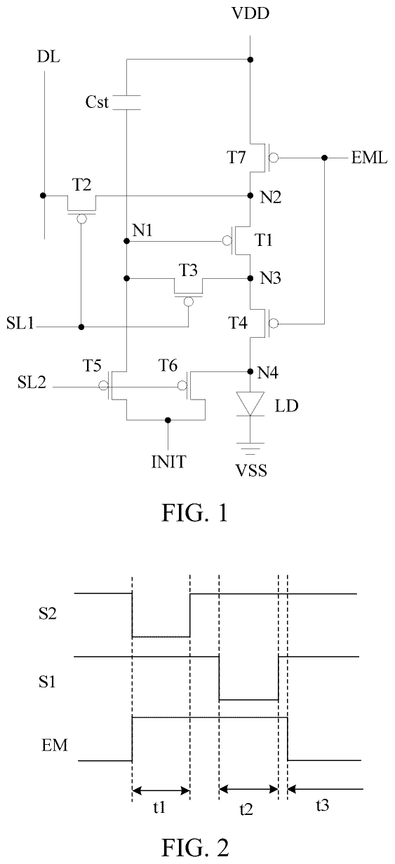

FIG. 1 is an equivalent circuit diagram of a pixel circuit according to at least one embodiment of the present disclosure. In some examples, as shown in FIG. 1, the pixel circuit of this example may have a structure of 7T1C, i.e., first transistor T1 to seventh transistor T7 and a storage capacitor Cst. A gate of the first transistor T1 is electrically connected to a first node N1, a first electrode of the first transistor T1 is electrically connected to a second node N2, and a second electrode of the first transistor T1 is electrically connected to a third node N3. The first transistor T1 may also be referred to as a drive transistor. A gate of the second transistor T2 is electrically connected to a first scan line SL1, a first electrode of the second transistor T2 is electrically connected to a data line DL, and a second electrode of the second transistor T2 is electrically connected to the second node N2. The second transistor T2 may also be referred to as a data writing transistor. A gate of the third transistor T3 is electrically connected to the first scan line SL1, a first electrode of the third transistor T3 is electrically connected to the first node N1, and a second electrode of the third transistor T3 is electrically connected to the third node N3. The third transistor T3 may also be referred to as a threshold compensation transistor. A gate of the fourth transistor T4 is electrically connected to a light emitting control line EML, a first electrode of the fourth transistor T4 is electrically connected to the third node N3, and a second electrode of the fourth transistor T4 is electrically connected to a fourth node N4. A gate of the seventh transistor T7 is electrically connected to the light emitting control line EML, a first electrode of the seventh transistor T7 is electrically connected to a first power supply line VDD, and a second electrode of the seventh transistor T7 is electrically connected to the second node N2. The fourth transistor T4 and the seventh transistor T7 may also be referred to as light emitting control transistors. A gate of the fifth transistor T5 is electrically connected to a second scan line SL2, a first electrode of the fifth transistor T5 is electrically connected to an initial signal line INIT, and a second electrode of the fifth transistor T5 is electrically connected to the first node N1. A gate of the sixth transistor T6 is electrically connected to the second scan line SL2, a first electrode of the sixth transistor T6 is electrically connected to the initial signal line INIT, and a second electrode of the sixth transistor T6 is electrically connected to the fourth node N4. The fifth transistor T5 and the sixth transistor T6 may also be referred to as reset control transistors. A first capacitor plate of the storage capacitor Cst is electrically connected to the first node N1, and a second capacitor plate of the storage capacitor Cst is electrically connected to the first power supply line VDD. A first electrode of the light emitting element LD is electrically connected to the fourth node N4, and the second electrode of the light emitting element LD is electrically connected to a second power supply line VSS. For example, the first electrode of the light emitting element LD may be an anode, and the second electrode of the light emitting element LD may be a cathode.

In this example, the first node N1 may be a connection point for the storage capacitor Cst, the first transistor T1, the third transistor T3, and the fifth transistor T5. The second node N2 may be a connection point for the first transistor T1, the second transistor T2, and the seventh transistor T7. The third node N3 may be a connection point for the first transistor T1, the third transistor T3 and the fourth transistor T4. The fourth node N4 may be a connection point for the fourth transistor T4, the sixth transistor T6 and the light emitting element LD.

In some examples, the first transistor T1 to the seventh transistor T7 may all be P-type transistors, or all may be N-type transistors. Use of transistors of a same type in a pixel circuit may simplify a process flow, reduce process difficulties of a transparent display panel, and improve a product yield. In some possible implementation modes, some of the transistors in the first transistor T1 to the seventh transistor T7 may be N-type transistors (e.g., the third transistor T3 and the fifth transistor T5), and the remaining transistors may be P-type transistors.

In some examples, the first power supply line VDD may be configured to provide a constant first voltage signal to the pixel circuit, and the second power supply line VSS may be configured to provide a constant second voltage signal to the pixel circuit. The first voltage signal may be greater than the second voltage signal. The first scan line SL1 may be configured to provide a first scan signal S1 to the pixel circuit, and the second scan line SL2 may be configured to provide a second scan signal S2 to the pixel circuit. In some examples, the second scan line electrically connected to an n-th row of pixel circuits may be electrically connected to the first scan line of an (n−1)-th row of pixel circuits, to be input with a first scan signal S1 (n−1), i.e., the second scan signal S2 (n) may be the same as the first scan signal S1 (n−1), and n may be an integer greater than 0. In this way, signal lines of the transparent display panel can be reduced to achieve a narrow bezel design of the transparent display panel. The data line DL may be configured to provide a data signal to the pixel circuit. The light emitting control line EML may be configured to provide a light emitting control signal EM to the pixel circuit. The initial signal line INIT may be configured to provide an initial signal to the pixel circuit. A magnitude of the initial signal may be between, but not limited to, the first voltage signal and the second voltage signal.

An operating process of the pixel circuit is explained below. FIG. 2 is an operating timing diagram of the pixel circuit shown in FIG. 1. The description is given by taking a case in which a plurality of transistors included in the pixel circuit shown in FIG. 1 are all P-type transistors as an example.

In some exemplary implementation modes, as shown in FIG. 2, the working operating of the pixel circuit may include a first time period t1, a second time period t2, and a third time period t3 during a frame display duration.

In the first time period t1, the second scan line SL2 provides a second scan signal S2 of a low level, and the fifth transistor T5 and the sixth transistor T6 are turned on. The fifth transistor T5 is turned on, to provide an initial signal to the first node N1 to initialize the first node N1, and the sixth transistor T6 is turned on, to provide an initial signal to the fourth node N4 to initialize the fourth node N4. The light emitting control line EML provides a light emitting control signal EM of a high level, and the fourth transistor T4 and the seventh transistor T7 are turned off. The first scan line SL1 provides a first scan signal S2 of a high level, and the second transistor T2 and the third transistor T3 are turned off.

In the second time period t2, the first scan line SL1 provides a first scan signal S1 of a low level, the second transistor T2 and the third transistor T3 are turned on, and the first transistor T1 may be connected in a form of a diode through the third transistor T3. The data line DL provides a data signal, which is transmitted to the first node N1 via the second transistor T2, the first transistor T1 and the third transistor T3. The first transistor T1 is connected in the form of the diode, so that a difference between a voltage of the data signal and a threshold voltage of the first transistor T1 is transmitted to the first node N1, and the voltage of the first node N1 is stored in the storage capacitor Cst.

In the third time period t3, the first scan line SL1 provides a first scan signal S1 of a high level, the second scan line SL2 provides a second scan signal S2 of a high level, and the light emitting control line EML provides a light emitting control signal EM of a low level. The fourth transistor T4 and the seventh transistor T7 are turned on, and a drive current flows from the first power supply line VDD through the seventh transistor T7, the first transistor T1, the fourth transistor T4 and the light emitting element LD to the second power supply line VSS. The drive current is controlled by the voltage of the first node N1, and the voltage of the data signal and a voltage corresponding to the threshold voltage of the first transistor T1 may offset the threshold voltage of the first transistor T1 in the third time period t3, so that the drive current corresponds to the data signal and is irrelevant to the threshold voltage offset of the first transistor T1. The pixel circuit according to this embodiment may better compensate the threshold voltage of the first transistor T1.

Solutions of this embodiment will be described below through multiple examples.

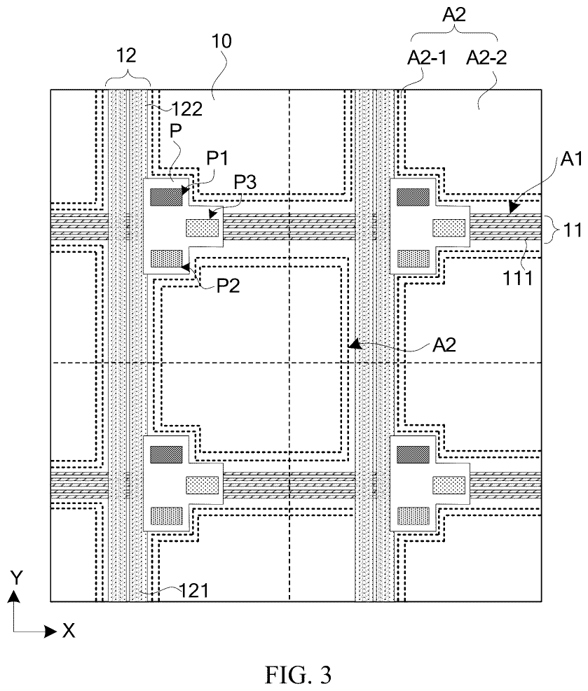

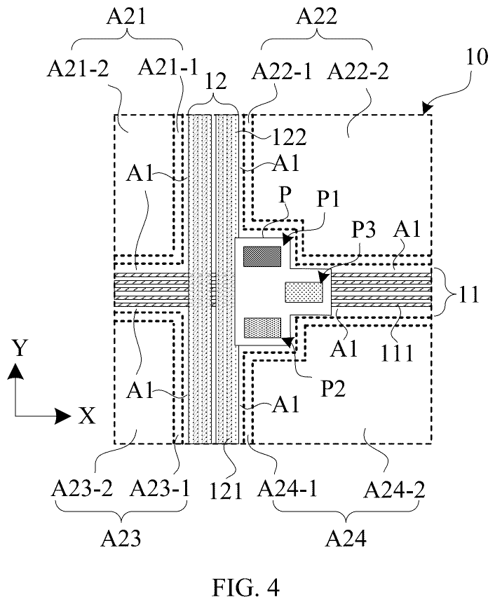

FIG. 3 is a schematic partial view of a transparent display panel according to at least one embodiment of the present disclosure. FIG. 4 is a schematic diagram of a repeating unit of a transparent display panel according to at least one embodiment of the present disclosure. FIG. 3 is formed by four repeating units as shown in FIG. 4 arranged in a 2×2 array.

In some examples, as shown in FIGS. 3 and 4, the transparent display panel may include a plurality of repeating units 10 arranged in an array on a substrate. For example, the repeating units 10 are substantially quadrilateral, for example rectangular. Each repeating unit 10 may include a non-transmissive region A1 and a plurality of transmissive regions A2 (for example, the transmissive region A2 of each repeating unit 10 may include a first transmissive sub-region A21, a second transmissive sub-region A22, a third transmissive sub-region A23 and a fourth transmissive sub-region A24). Adjacent transmissive regions A2 may be spaced apart by the non-transmissive region A1, the transmissive region A2 may include a hollowed-out region A2-2 and a transition region A2-1 located between the non-transmissive region A1 and the hollowed-out region A2-2, and at least one insulation layer in the hollowed-out region A2-2 is provided in a hollowed-out structure. In each repeating unit 10, the first light transmission sub-region A21 may include a first transition sub-region A21-1 and a first hollow-out sub-region A21-2, the second light transmission sub-region A22 may include a second transition sub-region A22-1 and a second hollow-out sub-region A22-2, the third light transmission sub-region A23 may include a third transition sub-region A23-1 and a third hollow-out sub-region A23-2, and the fourth light transmission sub-region A24 may include a fourth transition sub-region A24-1 and a fourth hollow-out sub-region A24-2. The non-transmissive regions A1 of adjacent repeating units 10 may be interconnected. The transmissive sub-regions of adjacent repeating units 10 may be interconnected. For example, the transmissive sub-regions of four repeating units 10 arranged in the 2×2 array may be interconnected to form a larger transmissive region A2. For example, the fourth transmissive sub-region A24 of the repeating unit in the first row and the first column, the third transmissive sub-region A23 of the repeating unit in the first row and the second column, the second transmissive sub-region A22 of the repeating unit in the second row and the first column, and the first transmissive sub-region A21 of the repeating unit in the second row and the second column may be interconnected to form a larger transmissive region A2. The transmissive region A2 may be surrounded by non-transmissive regions A1.

In some examples, in a repeating unit, a total area of the transmissive sub-regions may be greater than an area of the non-transmissive region. A total area of the transmissive regions of the transparent display panel may be greater than 45% of a total area of the transparent display panel, for example, it may be about 48.5%, 79.3%, 82.1%, or 85%. However, the embodiment is not limited thereto. In some examples, the area proportion of the transmissive regions and the proportion of hollowed-out regions can be set according to the actual application requirements. The larger the area proportion of the transmissive regions and hollowed-out regions, the greater the transmittance of the transparent display panel, and the higher the transparency of transparent display panel, that is, the better the transparent display effect.

In some examples, as shown in FIGS. 3 and 4, a non-transmissive region A1 of a repeating unit 10 may include: a pixel unit P and a set of first traces 11 and a set of second traces 12 electrically connected to the pixel unit P. The set of first traces 11 may include: a plurality of first signal lines 111 extending in a first direction X. The plurality of first signal lines 111 may be sequentially arranged in the second direction Y. The plurality of first signal lines 111 may be disposed in a same layer. The set of second traces 12 may include: a plurality of third signal lines 121 and a plurality of fourth signal lines 122 extending in the second direction Y. The plurality of third signal lines 121 may be sequentially arranged in the first direction X and the plurality of fourth signal lines 122 may be sequentially arranged in the first direction X. The plurality of third signal lines 121 may be disposed in a same layer, and the plurality of fourth signal lines 122 may be disposed in a same layer. For example, the plurality of fourth signal lines 122 may be located on a side of the plurality of third signal lines 121 away from the substrate. An orthographic projection of at least one fourth signal line 122 on the substrate may cover an orthographic projection of at least two third signal lines 121 on the substrate. For example, an orthographic projection of one fourth signal line 122 on the substrate may cover an orthographic projection of two third signal lines 121 on the substrate. In some examples, the plurality of fourth signal lines 122 of the set of second traces 12 may include: a first power supply line and a second power supply line. The second power supply line may be located on a side of the first power supply line close to the pixel unit P in the first direction X. In other words, the second power supply line may be adjacent to the pixel unit P, and the first power supply line may be located on a side of the second power supply line away from the pixel unit P.

In some examples, as shown in FIG. 3, the plurality of repetition units 10 are arranged in an array such that the non-transmissive regions A1 of adjacent repetition units 10 may be interconnected. A plurality of first signal lines 111 within the non-transmissive regions A1 of the repetition units 10 adjacent in a first direction X may be correspondingly interconnected, a plurality of third signal lines 121 within the non-transmissive regions A1 of the repetition units 10 adjacent in a second direction Y may be correspondingly interconnected, and a plurality of fourth signal lines 122 within the non-transmissive regions A1 of the repetition units 10 adjacent in a second direction Y may be correspondingly interconnected. After the plurality of repetition units 10 are arranged in the array, the plurality of first signal lines 111 may transmit signals in the first direction X, and the plurality of third signal lines 121 and the plurality of fourth signal lines 122 may transmit signals in the second direction Y.

In some examples, as shown in FIGS. 3 and 4, a pixel unit P within a non-transmissive region A1 of a repeating unit 10 may include a first sub-pixel P1 emitting light of a first color, a second sub-pixel P2 emitting light of a second color, and a third sub-pixel P3 emitting light of a third color. The first sub-pixel P1, the second sub-pixel P2, and the third sub-pixel P3 may be arranged in a zigzag pattern. For example, the light of the first color may be red light, the light of the second color may be blue light, and the light of the third color light may be green light. However, the embodiment is not limited thereto.

In some examples, the first sub-pixel P1 may include: a first pixel circuit and a first light emitting element electrically connected to the first pixel circuit. A second sub-pixel P2 may include: a second pixel circuit and a second light emitting element electrically connected to the second pixel circuit. The third sub-pixel P3 may include: a third pixel circuit and a third light emitting element electrically connected to the third pixel circuit. An orthographic projection of the first light emitting element on the substrate overlaps with an orthographic projection of the first pixel circuit on the substrate. An orthographic projection of the second light emitting element on the substrate overlaps with an orthographic projection of the second pixel circuit on the substrate. An orthographic projection of the third light emitting element on the substrate overlaps with an orthographic projection of the third pixel circuit on the substrate. For example, the first pixel circuit, the second pixel circuit and the third pixel circuit may be of the 7T1C structure as shown in FIG. 1, and the first light emitting element, the second light emitting element and the third light emitting element may be elements with a light emitting area no larger than 1×10⁵ um², such as a micro-LED. In this example, the superimposition design of the pixel circuit and the corresponding light emitting element electrically connected to the pixel circuit can reduce the area of the non-transmissive regions A1 and increase a pixel aperture ratio, thereby increasing the area of the transmissive regions.

In some examples, sizes of first transistors in pixel circuits electrically connected to light emitting elements emitting light of different colors may be different due to differences in optoelectronic properties of the light emitting elements emitting light of different colors. For example, a channel aspect ratio (i.e., a ratio of a size in the first direction to a size in the second direction) of a first transistor of a pixel circuit electrically connected to a light emitting element emitting red light may be greater than a channel aspect ratio of a first transistor of a pixel circuit electrically connected to a light emitting element emitting blue or green light.

FIG. 5 is a schematic partial sectional view of a transparent display panel according to at least one embodiment of the present disclosure. In some examples, as shown in FIG. 5, in a direction perpendicular to the transparent display panel, a non-transmissive region A1 of a repeating unit may include: a substrate 100, and a circuit structure layer 21, a light emitting structure layer 22, and a cover layer 23 (which may be referred to as a protective layer 23) disposed sequentially on the substrate 100. The circuit structure layer 21 may at least include: a plurality of pixel circuits (e.g., a first pixel circuit, a second pixel circuit, and a third pixel circuit). The circuit structure layer 21 in FIG. 5 is illustrated by taking only a partial structure of one transistor and one storage capacitor of one pixel circuit as an example. The circuit structure layer 21 may include: a semiconductor layer 210, a first conductive layer 211, a second conductive layer 212, a third conductive layer 213, and a fourth conductive layer 214 disposed sequentially on the substrate 100. In some examples, the semiconductor layer 210 may include active layers of transistors of the plurality of pixel circuits. The first conductive layer 211 may at least include: gates of the transistors of the plurality of pixel circuits and a capacitor plate of the storage capacitor. The second conductive layer 212 may at least include: another capacitor plate of the storage capacitor of the plurality of pixel circuits. The third conductive layer 213 may at least include: a plurality of connection electrodes. The fourth conductive layer 214 may at least include: a first conductive part, a second conductive part, and a second power supply line VSS.

In some examples, as shown in FIG. 5, a first insulation layer 101 may be provided between the semiconductor layer 210 and the first conductive layer 211, a second insulation layer 102 may be provided between the first conductive layer 211 and the second conductive layer 212, a third insulation layer 103 may be provided between the second conductive layer 212 and the third conductive layer 213, and a fourth insulation layer 104 and a fifth insulation layer 105 may be provided between the third conductive layer 213 and the fourth conductive layer 214. A sixth insulation layer 106 and a seventh insulation layer 107 may be provided on a side of the fourth conductive layer 214 away from the substrate 100. For example, the first insulation layer 101 to the fourth insulation layers 104 and the sixth insulation layer 106 may be inorganic insulation layers, and the fifth insulation layer 105 and the seventh insulation layer 107 may be organic insulation layers. However, the embodiment is not limited thereto. In some examples, as shown in FIG. 5, a buffer layer b0 may further be provided between the substrate 100 and the semiconductor layer 210, for improving a water and oxygen resistance capability of the substrate 100.

In an exemplary implementation mode, the buffer layer b0 and at least one of the first insulation layer 101 to the seventh insulation layer 107 in the hollowed-out region A2-2 are provided in hollowed-out structures. For example, the buffer layer b0 and the first insulation layer 101 to the seventh insulation layer 107 in the hollowed-out region A2-2 are all provided in hollowed-out structures to improve the sharpness of the display panel, thereby improving quality of the displayed picture. In an exemplary implementation mode, the buffer layer b0, the first insulation layer 101 to the seventh insulation layer 107 may be formed by a single etching process or by a plurality of etching processes. For forming by a single etching process, after the buffer layer b0, the first insulation layer 101 to the seventh insulation layer 107 are formed, the buffer layer b0, the first insulation layer 101 to the seventh insulation layer 107 are etched by a single etching process to form a hollowed-out structure in a hollowed-out region. For forming by a plurality of etching processes, i.e., after at least one insulation layer is etched once after formation thereof, e.g., after the buffer layer b0, the first insulation layer 101 to the fourth insulation layer 104 are formed, the first insulation layer 101 to the fourth insulation layer 104 of the hollowed-out region A2-1 are etched away, after the fifth insulation layer 105 is formed, the fifth insulation layer 105 of the hollowed-out region A2-1 is etched away separately, after the sixth insulation layer 106 is formed, the sixth insulation layer 106 of the hollowed-out region A2-1 is etched away separately, and after the seventh insulation layer 107 is formed, the seventh insulation layer 107 of the hollowed-out region A2-1 is etched off separately. However, the embodiment is not limited thereto.

In an exemplary implementation mode, after any one of the second insulation layer 102 to the seventh insulation layer 107 is formed, the insulation layers of the hollowed-out region A2-2 may be subjected to UV exposure so as to remove the insulation layers of the hollowed-out region A2-2 in order to avoid residual metal of the conductive layers or PR adhesive of the insulation layers, thereby avoiding affecting a transmittance of the hollowed-out region A2-2.

In some examples, the light emitting structure layer 22 may include: a plurality of light emitting elements (e.g., a first light emitting element, a second light emitting element, and a third light emitting element). Taking one light emitting element as an example, as shown in FIG. 5, the light emitting element may include: a light emitting part 220, a first electrode 221 and a second electrode 222 connected to the light emitting part 220. The first electrode 221 is connected to a first end of the light emitting part 220, and the second electrode 222 is connected to a second end of the light emitting part 220. For example, the first electrode 221 of the light emitting element may be an anode, and the second electrode 222 of the light emitting element may be a cathode. The first electrode 221 may be electrically connected to the pixel circuit through the first conductive part, and the second electrode 222 may be electrically connected to the second power supply line VSS through the second conductive part. However, the embodiment is not limited thereto. A protective layer 23 may further be provided on a side of the light emitting element away from the substrate 100, to prevent the light emitting element from falling off due to external force (e.g., rubbing) in a subsequent process or transportation. A material of the protective layer 23 may be silicone.

In some examples, as shown in FIG. 5, in a direction perpendicular to the transparent display panel, the transmissive region A2 may include: the substrate 100, the buffer layer b0 and the first insulation layer 101 to the sixth insulation layer 106 disposed sequentially on the substrate 100, and a cover layer 23. The buffer layer b0 and at least one of the first insulation layer 101 to the seventh insulation layer 107 may be in a hollowed-out design in the transmissive region A2 to enhance a transmittance of the transmissive region A2. However, the embodiment is not limited thereto. In some other examples, the fifth insulation layer and the seventh insulation layer may be in a hollowed-out design in the transmissive region A2 to further enhance the transmittance of the transmissive region A2.

A manufacturing process of the transparent display panel will be exemplarily described below. The “patterning process” or “a process of patterning” mentioned in the present disclosure includes processes, such as photoresist coating, mask exposure, development, etching and photoresist stripping, for metal materials, inorganic materials or transparent conductive materials, and includes processes, such as organic material coating, mask exposure and development, for organic materials. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a substrate using deposition, coating, or other processes. If the “thin film” does not need to be processed by a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“E and F are disposed on a same layer” in the present disclosure means that E and F are formed simultaneously by a same patterning process or that surfaces of E and F near the substrate are at substantially same distance from the substrate, or that the surfaces of E and F near the substrate are in direct contact with a same film layer. The “thickness” of a film layer is a size of the film layer in a direction perpendicular to a plane where the substrate is located. In an exemplary embodiment of the present disclosure, “an orthogonal projection of E includes an orthogonal projection of F” refers to that a boundary of the orthogonal projection of E falls within a boundary of the orthogonal projection of F, or the boundary of the orthogonal projection of E is coincided with the boundary of the orthogonal projection of F.

In some exemplary implementation modes, a manufacturing process of a transparent display panel may include following operations.
(1) A substrate is provided. In some examples, the substrate may be a rigid substrate, such as a glass substrate or a quartz substrate, or, the substrate may be a flexible substrate, such as an organic resin substrate. In some examples, the substrate may be a glass substrate. However, the embodiment is not limited thereto.
(2) A semiconductor layer is formed. In some examples, a semiconductor thin film is deposited on the substrate, and the semiconductor thin film is patterned by a patterning process to form a semiconductor layer in a non-transmissive region.

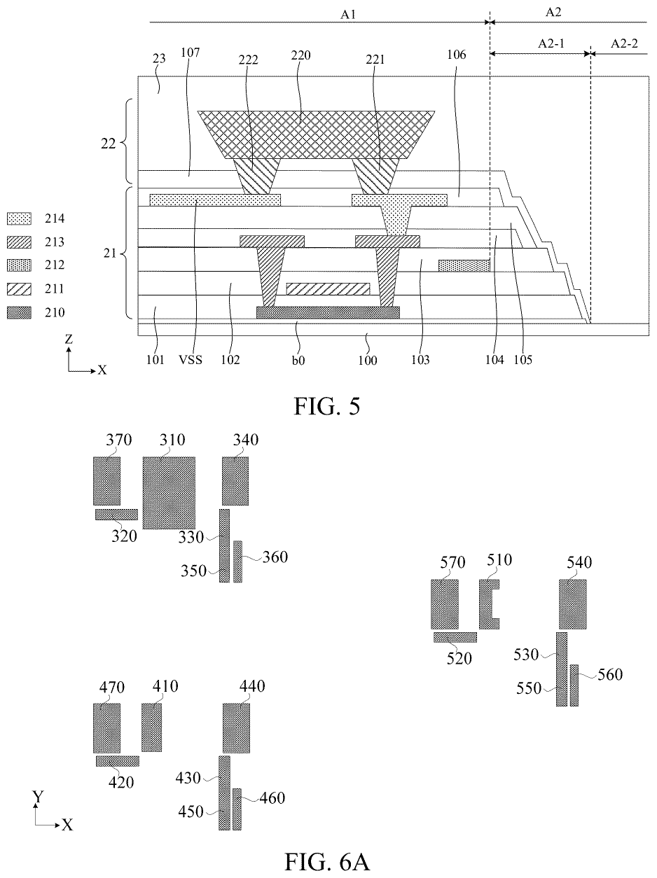

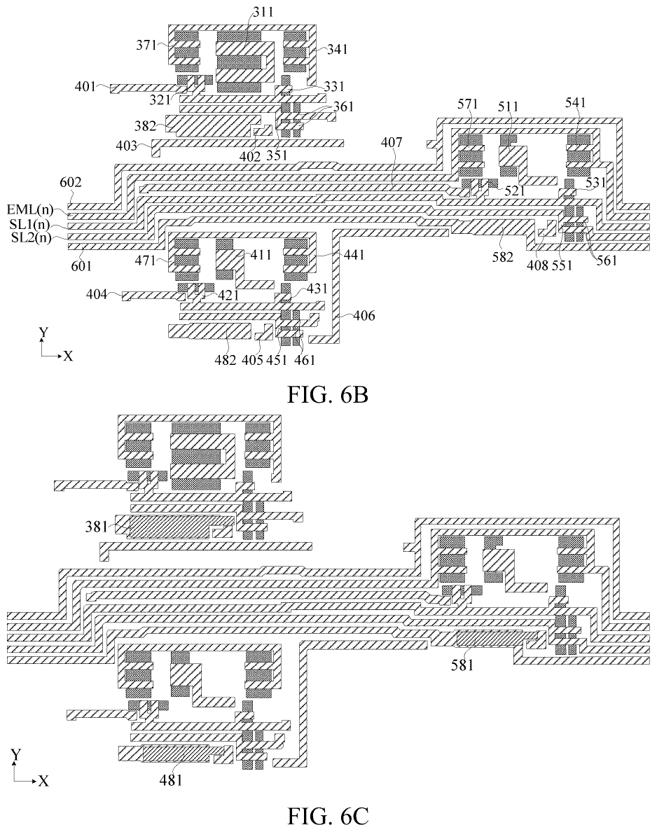

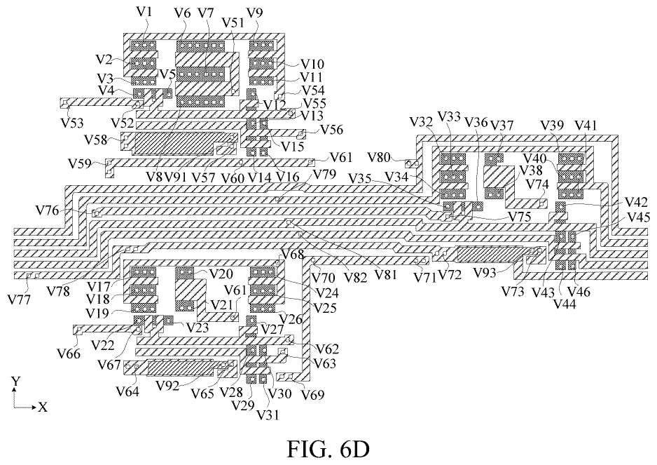

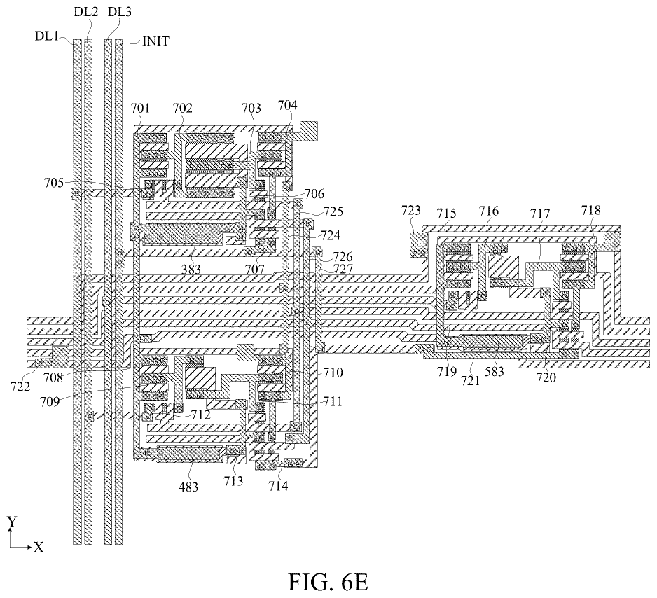

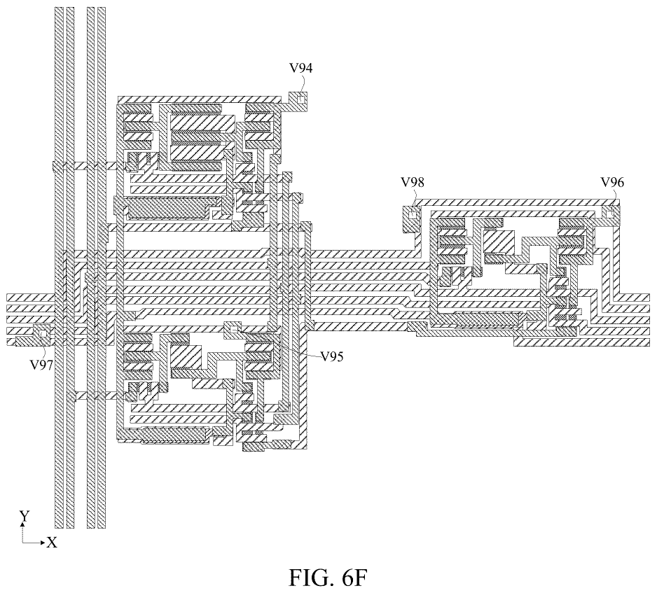

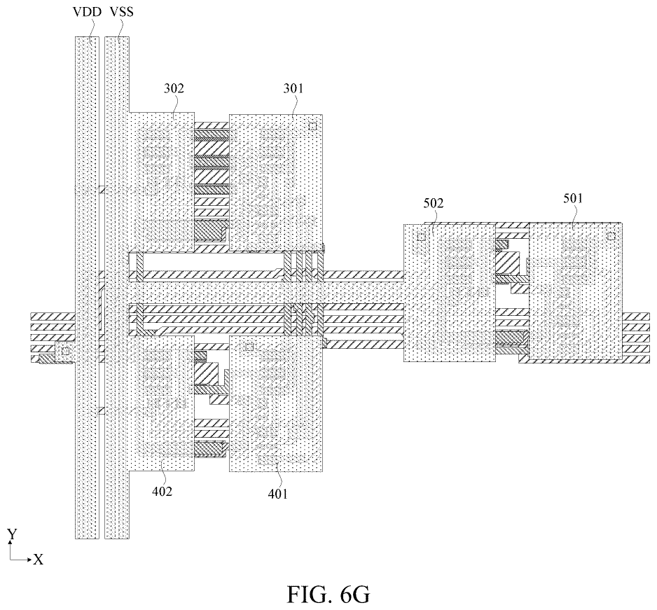

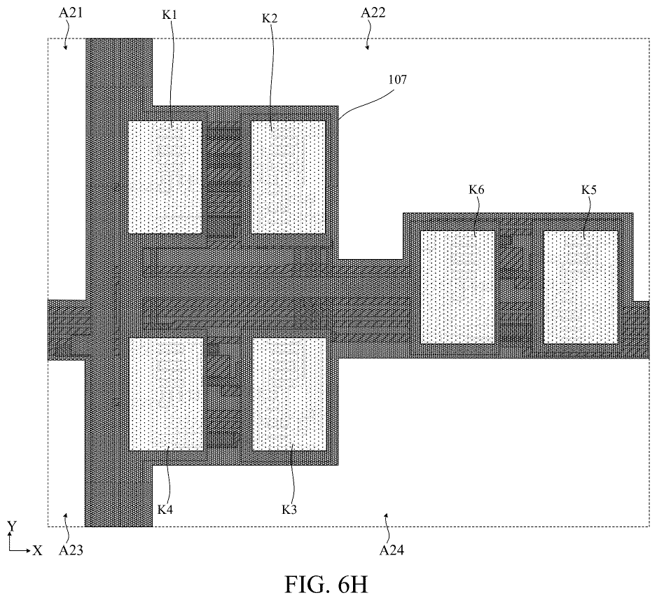

FIG. 6A is a schematic diagram of a semiconductor layer of a repeating unit according to at least one embodiment of the present disclosure. In some examples, as shown in FIG. 6A, the semiconductor layer of the non-transmissive region of the repeating unit may at least include: active layers of a plurality of transistors of a plurality of pixel circuits (including, for example, a first active layer 310 of a first transistor to a seventh active layer 370 of a seventh transistor in a first pixel circuit, a first active layer 410 of a first transistor to a seventh active layer 470 of a seventh transistor in a second pixel circuit, and a first active layer 510 of a first transistor to a seventh active layer 570 of a seventh transistor in the third pixel circuit). In an exemplary implementation mode, the third active layer 330 and the fifth active layer 350 of the first pixel circuit may be of an integral structure, the third active layer 430 and the fifth active layer 450 of the second pixel circuit may be of an integral structure, and the third active layer 530 and the fifth active layer 550 of the third pixel circuit may be of an integral structure.

In some examples, the semiconductor layer may be made of one or more materials such as amorphous Indium Gallium Zinc Oxide (a-IGZO), Zinc Oxynitride (ZnON), Indium Zinc Tin Oxide (IZTO), amorphous Silicon (a-Si), polysilicon (p-Si), sexithiophene, and polythiophene. That is, the present disclosure is applicable to transistors manufactured based on an oxide technology, a silicon technology, and an organic matter technology. For example, a material of the semiconductor layer may be polycrystalline Silicon (p-Si). However, the embodiment is not limited thereto.
(3) Forming a first conductive layer. In some examples, a first insulation thin film is deposited on the substrate on which the aforementioned structures are formed, and the first insulation thin film is patterned by a patterning process to form a first insulation layer covering the semiconductor layer. Subsequently, a first conductive thin film is deposited, and the first conductive thin film is patterned by a patterning process to form a first conductive layer in the non-transmissive region.

FIG. 6B is a schematic view of a first conductive layer of a repeating unit according to at least one embodiment of the present disclosure. In some examples, as shown in FIG. 6B, the first conductive layer of the non-transmissive region of the repeating unit may at least include gates of a plurality of transistors of a plurality of pixel circuits and capacitor plates of storage capacitors (e.g., a gate 311 of the first transistor, a gate 321 of the second transistor, a gate 331 of the third transistor, a gate 341 of the fourth transistor, a gate 351 of the fifth transistor, a gate 361 of the sixth transistor, a gate 371 of the seventh transistor, and a second capacitor plate 382 of a storage capacitor of the first pixel circuit; a gate 411 of the first transistor, a gate 421 of the second transistor, a gate 431 of the third transistor, a gate 441 of the fourth transistor, a gate 451 of the fifth transistor, a gate 461 of the sixth transistor, a gate 471 of the seventh transistor, and a second capacitor plate 482 of a storage capacitor of the second pixel circuit; a gate 511 of the first transistor, a gate 521 of the second transistor, a gate 531 of the third transistor, a gate 541 of the fourth transistor, a gate 551 of the fifth transistor, a gate of the sixth transistor 561, a gate 571 of the seventh transistor, and a second capacitor plate 582 of a storage capacitor of the third pixel circuit), a plurality of connection electrodes (for example, a first connection electrode 401 to an eighth connection electrode 408), a light emitting control line EML (n), a first scan line SL1 (n), a second scan line SL2 (n), a first power supply connection line 601, and a second power supply connection line 602.

In some examples, as shown in FIG. 6B, in the first pixel circuit, the gate 341 of the fourth transistor and the gate 371 of the seventh transistor may be of an integrated structure, the gate 321 of the second transistor and the gate 331 of the third transistor may be of an integrated structure, and the gate 351 of the fifth transistor and the gate 361 of the sixth transistor may be of an integrated structure. The first transistor to the seventh transistor of the first pixel circuit may all be dual-gate transistors. In the second pixel circuit, the gate 441 of the fourth transistor and the gate 471 of the seventh transistor may be of an integrated structure, the gate 421 of the second transistor and the gate 431 of the third transistor may be of an integrated structure, and the gate 451 of the fifth transistor and the gate 461 of the sixth transistor may be of an integrated structure. The first transistor to the seventh transistor of the second pixel circuit may all be dual-gate transistors. In the third pixel circuit, the gate 541 of the fourth transistor and the gate 571 of the seventh transistor may be of an integrated structure, the gate 521 of the second transistor and the gate 531 of the third transistor may be of an integrated structure, and the gate 551 of the fifth transistor and the gate 561 of the sixth transistor may be of an integrated structure. The first transistor to the seventh transistor of the third pixel circuit may all be dual-gate transistors. This example can enhance a driving capability, improve current saturation of the light emitting element, and prevent and reduce occurrence of leakage current by use of the dual-gate transistors.

In some examples, as shown in FIG. 6B, the second power connection line 602, the light emitting control line EML(n), the first scan line SL1(n), the second scan line SL2(n), and the first power connection line 601 may be arranged sequentially in the second direction Y and extend in the first direction X. The second power connection line 602, the light emitting control line EML(n), the first scan line SL1(n), the second scan line SL2(n), and the first power connection line 601 may be located between the first pixel circuit and the second pixel circuit in the second direction Y.

In some examples, the first power connection line 601 and the second capacitor plate 582 of the storage capacitor of the third pixel circuit may be of an integrated structure. as shown in FIG. 6B. The light emitting control line EML(n) and the gate 571 of the seventh transistor and the gate 541 of the fourth transistor of the third pixel circuit may be of an integrated structure. The first scan line SL1(n) and the gate 521 of the second transistor and the gate 531 of the third transistor of the third pixel circuit may be of an integrated structure. The second scan line SL2(n) and the gate 551 of the fifth transistor and the gate 561 of the sixth transistor of the third pixel circuit may be of an integrated structure. However, the embodiment is not limited thereto.
(4) Forming a second conductive layer. In some examples, a second insulation thin film is deposited on the substrate on which the aforementioned structures are formed, and the second insulation thin film is patterned by a patterning process to form a second insulation layer covering the first conductive layer; subsequently, a second conductive thin film is deposited, and the second conductive thin film is patterned by a patterning process to form a second conductive layer in the non-transmissive region.

FIG. 6C is a schematic diagram of a second conductive layer of a repeat unit according to at least one embodiment of the present disclosure. In some examples, as shown in FIG. 6C, the second conductive layer of the non-transmissive region of the repeating unit may at least include: the other capacitor plates of the storage capacitors of the plurality of pixel circuits (including, for example, a first capacitor plate 381 of the storage capacitor of the first pixel circuit, a first capacitor plate 481 of the storage capacitor of the second pixel circuit, and a first capacitor plate 581 of the third pixel circuit).
(5) A third insulation layer is formed. In some examples, a third insulation thin film is deposited on the substrate on which the aforementioned structures are formed, and the third insulation thin film is patterned by a patterning process to form a third insulation layer.

FIG. 6D is a schematic diagram of a third insulation layer of a repeating unit according to at least one embodiment of the present disclosure. In some examples, as shown in FIG. 6D, the third insulation layer of the non-transmissive region of the repeating unit is provided with a plurality of vias, which may include, for example, a first via V1 to forty-sixth via V46 exposing a surface of the semiconductor layer, a fifty-first via V51 to eighty-second via V82 exposing a surface of the first conductive layer, a ninety-first via V91 to ninety-third via V93 exposing a surface of the second conductive layer.
(6) Forming a third conductive layer. In some examples, a third conductive thin film is deposited on the substrate on which the aforementioned structures are formed, and the third conductive thin film is patterned by a patterning process to form a third conductive layer in the non-transmissive region.

FIG. 6E is a schematic diagram of a third conductive layer of a repeating unit according to at least one embodiment of the present disclosure. In some examples, as shown in FIG. 6E, the third conductive layer of the non-transmissive region of the repeating unit may at least include: a plurality of connection electrodes (e.g., eleventh connection electrode 701 to thirty-seventh connection electrode 727), a third capacitor plate 383 of the first pixel circuit, a third capacitor plate 483 of the second pixel circuit, a third capacitor plate 583 of the third pixel circuit, a plurality of data lines (e.g. data line DL1 to data line DL3), and an initial signal line INIT.

In some examples, as shown in FIG. 6E, the data lines DL1 to DL3 and the initial signal line INIT may be adjacent to each other and arranged sequentially in the first direction X and all extend in the second direction Y. The data lines DL1 to DL3 and the initial signal line INIT may be located at a side of the first pixel circuit and the second pixel circuit away from the third pixel circuit in the first direction X. An orthographic projection of the data lines DL1 to DL3 and the initial signal line INIT located in the third conductive layer on the substrate may overlap with an orthographic projection of the light emitting control line EML(n), the first scan line SL1(n), the second scan line SL2(n), the first power connection line 601 and the second power connection line 602 located in the first conductive layer on the substrate.

In some examples, as shown in FIGS. 6A to 6E, the eleventh connection electrode 701 may be electrically connected to the seventh active layer 370 of the seventh transistor of the first pixel circuit through three first vias V1 arranged side by side and three third vias V3 arranged side by side, and may also be electrically connected to the second capacitor plate 382 through two fifty-eighth vias V58 arranged vertically. The eleventh connection electrode 701 and the third capacitor plate 383 may be of an integrated structure. The twelfth connection electrode 702 may be electrically connected to the first active layer 310 of the first transistor of the first pixel circuit through six sixth vias V6 arranged side by side and six eighth vias V8 arranged side by side, and may also be electrically connected to the seventh active layer 370 of the seventh transistor through three second vias V2 arranged side by side, and may also be electrically connected to the second active layer 320 of the second transistor through a fifth via V5. The thirteenth connection electrode 703 may be electrically connected to the first active layer 310 of the first transistor through six seventh vias V7 arranged side by side, and may also be electrically connected to the fourth active layer 340 of the fourth transistor through three tenth vias V10 arranged side by side, and may also be electrically connected to the third active layer 330 of the third transistor through a twelfth via V12. The fourteenth connection electrode 704 may be electrically connected to the fourth active layer 340 of the fourth transistor through three ninth vias V9 arranged side by side and three eleventh vias V11 arranged side by side, and may also be electrically connected to the sixth active layer 360 of the sixth transistor through a fifteenth vias V15. The fifteenth connection electrode 705 may be electrically connected to the second active layer 320 of the second transistor through a fourth via V4, and may also be electrically connected to the first connection electrode 401 through a fifty-second via V52. The first connection electrode 401 may be electrically connected to the first data line DL1 through the fifty-third via V53. The sixteenth connection electrode 706 may be electrically connected to the gate 311 of the first transistor through a fifty-first via V51, may also be electrically connected to the fifth active layer 350 of the fifth transistor through a thirteenth via V13, may also be electrically connected to the first capacitor plate 381 of the storage capacitor through a ninety-first via V91, and may also be electrically connected to the second connection electrode 402 through a fifty-seventh via V57. The seventeenth connection electrode 707 may be electrically connected to the fifth active layer 350 of the fifth transistor through a fourteenth via V14, may also be electrically connected to the sixth active layer 360 of the sixth transistor through a sixteenth via V16, and may also be electrically connected to the third connection electrode 403 through a sixtieth via V60. The third connection electrode 403 may be electrically connected to the initial signal line INIT through two fifty-ninth vias V59 arranged vertically, and may also be electrically connected to the thirty-seventh connection electrode 727 through a sixty-first via V61.

In some examples, as shown in FIGS. 6A to 6E, the eighteenth connection electrode 708 may be electrically connected to the seventh active layer 470 of the seventh transistor of the second pixel circuit through three seventeenth vias V17 arranged side by side and the nineteenth vias V19 arranged side by side, and may also be electrically connected to the second capacitor plate 382 of the storage capacitor of the second pixel circuit through two sixty-fourth vias V64 arranged side by side, and may also be electrically connected to the first power connection line 601 through two seventy-eighth vias V78 arranged side by side. The eighteenth connection electrode 708 and the third capacitor plate 483 of the second pixel circuit may be of an integrated structure. The eighteenth connection electrode 708 and the eleventh connection electrode 701 may be of an integrated structure. The nineteenth connection electrode 709 may be electrically connected to the seventh active layer 470 through three eighteenth vias V18 arranged side by side, and may also be electrically connected to the first active layer 410 through two twentieth vias V20 arranged side by side, and may also be electrically connected to the second active layer 420 through a twenty-third via V23. The twentieth connection electrode 710 may be electrically connected to the fourth active layer 440 through three twenty-fourth vias V24 arranged side by side and three twenty-sixth vias V26 arranged side by side, and may also be electrically connected to the sixth active layer 460 through a thirtieth via V30. The twenty-first connection electrode 711 may be electrically connected to the first active layer 410 through two twenty-first vias V21 arranged side by side, and may also be electrically connected to the fourth active layer 440 through three twenty-fifth vias V25 arranged side by side, and may also be electrically connected to the third active layer 430 through a twenty-seventh via V27. The twenty-second connection electrode 712 may be electrically connected to the second active layer 420 through a twenty-second via V22, and may also be electrically connected to the fourth connection electrode 404 through a sixty-seventh via V67. The fourth connection electrode 404 may be electrically connected to the data line DL2 through a sixty-sixth via V66. The twenty-third connection electrode 713 may be electrically connected to the gate 411 of the first transistor through a sixty-first via V61, and may also be electrically connected to the fifth active layer 450 of the fifth transistor through a twenty-eighth via V28, and may also be electrically connected to the fifth connection electrode 405 through a sixty-five via V65, and may also be electrically connected to the first capacitor plate 481 of the storage capacitor through a ninety-second via V92. The twenty-fourth connection electrode 714 may be electrically connected to the fifth active layer 450 through a twenty-ninth via V29, may also be electrically connected to the sixth active layer 460 through a thirty-first via V31, and may also be electrically connected to the sixth connection electrode 406 through two sixty-ninth vias V69 arranged side by side.

In some examples, as shown in FIGS. 6A to 6E, the twenty-fifth connection electrode 715 may be electrically connected to the seventh active layer 570 of the third pixel circuit through three thirty-second vias V32 arranged side by side and three thirty-fourth vias V34 arranged side by side, and may also be electrically connected to the second capacitor plate 582 of the storage capacitor through two seventy-second vias V72 arranged side by side. The twenty-fifth connection electrode 715 and the third capacitor plate 583 may be of an integrated structure. The twenty-sixth connection electrode 716 may be electrically connected to the seventh active layer 570 through three thirty-third vias V33 arranged side by side, and may also be electrically connected to the first active layer 510 through two thirty-seventh vias V37 arranged side by side, and may also be electrically connected to the second active layer 520 through a thirty-sixth via V36. The twenty-seventh connection electrode 717 may be electrically connected to the first active layer 510 through two thirty-eighth vias V38 arranged side by side, and may also be electrically connected to the fourth active layer 540 through three fortieth vias V40 arranged side by side, and may also be electrically connected to the third active layer 530 through a forty-second via V42. The twenty-eighth connection electrode 718 may be electrically connected to the fourth active layer 540 through three thirty-ninth vias V39 arranged side by side and three forty-first vias V41 arranged side by side, and may also be electrically connected to the sixth active layer 560 through a forty-fifth via V45. The twenty-ninth connection electrode 719 may be electrically connected to the second active layer 520 through the thirty-fifth via V35, and may also be electrically connected to the seventh connection electrode 407 through a seventy-fifth via V75. The seventh connection electrode 407 may be electrically connected to the data line DL3 through a seventy-sixth via V76. The thirtieth connection electrode 720 may be electrically connected to the gate 511 of the first transistor through a seventy-fourth via V74, and may also be electrically connected to the fifth active layer 550 through a forty-third via V43, and may also be electrically connected to the eighth connection electrode 408 through a seventy-third via V73, and may also be electrically connected to the first capacitor plate 581 through the ninety-third via V93. The thirty-first connection electrode 721 may be electrically connected to the sixth connection electrode 406 through two seventy-first vias V71 arranged side by side, and may also be electrically connected to the fifth active layer 550 through a forty-fourth via V44, and may also be electrically connected to the sixth active layer 560 through the forty-sixth via V46.

In some examples, as shown in FIGS. 6A to 6E, the thirty-second connection electrode 722 may be electrically connected to the first power connection line 601 through two seventy-seventh vias V77 arranged side by side. The thirty-third connection electrode 723 may be electrically connected to the second power connection line 602 through the two eightieth vias V80 arranged side by side. The thirty-fourth connection electrode 724 may be electrically connected to the gate 341 of the fourth transistor of the first pixel circuit through a fifty-fourth via V54, and may also be electrically connected to the light emitting control line EML(n) through a seventy-ninth via V79, and may also be electrically connected to the gate 341 of the fourth transistor of the second pixel circuit through a sixty-eighth via V68. The light emitting control line EML(n) and the gate 571 of the seventh transistor and the gate 541 of the fourth transistor of the third pixel circuit may be of an integrated structure. The thirty-fifth connection electrode 725 may be electrically connected to the gate 331 of the third transistor of the first pixel circuit a the fifty-fifth via V55, and may also be electrically connected to the first scan line SL1(n) through a eighty-first via V81, and may also be electrically connected to the gate 431 of the third transistor of the second pixel circuit through a sixty-second via V62. The first scan line SL1(n) and the gate 521 of the second transistor and the gate 531 of the third transistor of the third pixel circuit may be of an integrated structure. The thirty-sixth connection electrode 726 may be electrically connected to the gate 361 of the sixth transistor of the first pixel circuit through a fifty-sixth via V56, and may also be electrically connected to the second scan line SL2(n) through the eighty-second via V82, and may also be electrically connected to the gate 461 of the sixth transistor of the second pixel circuit through a sixty-third via V63. The second scan line SL2(n) and the gate 551 of the fifth transistor and the gate 561 of the sixth transistor of the third pixel circuit may be of an integrated structure. The thirty-seventh connection electrode 727 may be electrically connected to the sixth connection electrode 406 through a seventieth via V70. An initial signal may be transmitted through the initial signal line INIT, the third connection electrode 403, the thirty-seventh connection electrode 727, the sixth connection electrode 406, and the thirty-first connection electrode 721.

In the present disclosure, being arranged side by side means arrangement in the first direction X, and being arranged vertically means arrangement in the second direction Y.
(7) Forming a fourth insulation layer and a fifth insulation layer. In some examples, a fourth insulation thin film is deposited on the substrate on which the aforementioned structures are formed, and subsequently, a fifth insulation thin film is coated, and the fifth insulation film and the fourth insulation film are patterned by a patterning process to form a fifth insulation layer and a fourth insulation layer.

FIG. 6F is a schematic diagram of a fifth insulation layer of a repeating unit according to at least one embodiment of the present disclosure. In some examples, as shown in FIG. 6F, the fifth insulation layer of the non-transmissive region of the repeating unit is provided with a plurality of vias, which may include, for example: the ninety-fourth via V94 to the ninety-eighth via V98 that expose a surface of the third conductive layer. The ninety-fourth via V94 may expose a surface of the fourteenth connection electrode 704. The ninety-fifth via V95 may expose a surface of the twentieth connection electrode 710. The ninety-sixth via V96 may expose a surface of the twenty-eighth connection electrode 718. The ninety-seventh via V97 may a the surface of the thirty-second connection electrode 722. The ninety-eighth via V98 may expose a surface of the thirty-third connection electrode 723.
(8) Forming a fourth conductive layer. In some examples, a fourth conductive thin film is deposited on the substrate on which the aforementioned structures are formed, and the fourth conductive thin film is patterned by a patterning process to form the fourth conductive layer in the non-transmissive region.

FIG. 6G is a schematic diagram of a fourth conductive layer of a repeating unit according to at least one embodiment of the present disclosure. In some examples, as shown in FIG. 6G, the fourth conductive layer of the non-transmissive region of the repeating unit may at least include: a first power supply line VDD, a second power supply line VSS, a first conductive part 301, a second conductive part 302, a third conductive part 401, a fourth conductive part 402, a fifth conductive part 501, and a sixth conductive part 502. The second power supply line VSS and the first power supply line VDD may extend in the second direction Y. The first power supply line VDD may be located at a side of the second power supply line VSS away from the first pixel circuit and the second pixel circuit in the first direction X. The second power supply line VSS, the second conductive part 302, the fourth conductive part 402, and the sixth conductive part 502 may be of an integrated structure. In this example, by providing the second power supply line VSS, the second conductive part 302, the fourth conductive part 402, and the sixth conductive part 502 as an integrated structure, an area of the non-transmissive region can be reduced, thereby increasing an area of the transmissive region.

In some examples, as shown in FIG. 6G and FIG. 6E, an orthographic projection of the first power supply line VDD on the substrate may cover an orthographic projection of the data lines DL1 and DL2 on the substrate, and an orthographic projection of the second power supply line VSS on the substrate may cover an orthographic projection of the data line DL3 and the initial signal line INIT on the substrate.

In some examples, as shown in FIGS. 6E to 6G, the first conductive part 301 may be electrically connected to the fourteenth connection electrode 704 through the ninety-fourth via V94 to achieve an electrical connection with the first pixel circuit. The third conductive part 401 may be electrically connected to the twentieth connection electrode 710 through the ninety-fifth via V95 to achieve an electrical connection with the second pixel circuit. The fifth conductive part 501 may be electrically connected to the twenty-eighth connection electrode 718 through the ninety-sixth via V96 to achieve an electrical connection with the third pixel circuit. The sixth conductive part 502 may be electrically connected to the thirty-third connection electrode 723 through the ninety-eighth via V98 to achieve an electrical connection with the second power connection line 602. The second power supply line VSS may be electrically connected to the second power connection line 602 through the sixth conductive part 502 and the thirty-third connection electrode 723, thereby realizing a mesh transmission route of a second voltage signal. The first power supply line VDD may be electrically connected to the thirty-second connection electrode 722 through the ninety-seventh via V97 to achieve an electrical connection with the first power connection line 601. The first power supply line VDD may be electrically connected to the first power connection line 601 through the thirty-second connection electrode 722 to achieve a mesh transmission route of a first voltage signal. In this example, resistances of the first power supply line and the second power supply line can be reduced by realizing a mesh connection of the second power supply line and a mesh connection of the first power supply line.
(9) Forming a sixth insulation layer and a seventh insulation layer. In some examples, a sixth insulation thin film is deposited on the substrate on which the aforementioned structures are formed, and subsequently, a seventh insulation thin film is coated, and the seventh insulation thin film and the sixth insulation thin film are patterned by a patterning process to form a seventh insulation layer and a sixth insulation layer.

FIG. 6H is a schematic diagram of a seventh insulation layer of a repeating unit according to at least one embodiment of the present disclosure. In some examples, as shown in FIG. 6H, the seventh insulation layer of the non-transmissive region of the repeating unit may be provided with a plurality of openings, which may include, for example, a first opening K1 to a sixth opening K6 that expose a surface of the fourth conductive layer. The first opening K1 may expose a surface of the second conductive part 302, and a region of the second conductive part 302 exposed by the first opening K1 may serve as a cathode pad, which is to be subsequently bonded to a second electrode of a first light emitting element. The second opening K2 may expose a surface of the first conductive part 301, and a region of the first conductive part 301 exposed by the second opening K2 may be used as an anode pad, which is to be subsequently bonded to a first electrode of the first light emitting element. The third opening K3 can expose a surface of the third conductive part 401, and a region of the third conductive part 401 exposed by the third opening K3 may be used as an anode pad, which is to be subsequently bonded to a first electrode of a second light emitting element. The fourth opening K4 may expose a surface of the fourth conductive part 402, and a region of the fourth conductive part 402 exposed by the fourth opening K4 may serve as a cathode pad, which is to be subsequently bonded to a second electrode of the second light emitting element. The fifth opening K5 may expose a surface of the fifth conductive part 501, and a region of the fifth conductive part 501 exposed by the fifth opening K5 may serve as an anode pad, which is to be subsequently bonded to a first electrode of a third light emitting element. The sixth opening K6 may expose the surface of the sixth conductive part 502, and a region of the sixth conductive part 502 exposed by the sixth opening K6 may serve as a cathode pad, which is to be subsequently bonded to a second electrode of the third light emitting element. For example, an orthographic projection of the first opening K1 and the fourth opening K4 on the substrate may overlap with the orthographic projection of the second power supply line VSS on the substrate. A region of the non-transmissive region other than the first opening K1 to the sixth opening K6 may be covered by the seventh insulation layer and the sixth insulation layer. The seventh insulation layer in transmissive sub-regions (e.g., the first transmissive sub-region A21 to the fourth transmissive sub-region A24) other than the non-transmissive region of the repeating unit may be removed, and the sixth insulation layer may be retained. However, the embodiment is not limited thereto.

So far, the circuit structure layer is prepared and formed in the non-transmissive region. After this process, the transmissive region may only include: the substrate, and the first insulation layer to the sixth insulation layer provided sequentially on the substrate.

In some examples, the first insulation layer to the fourth insulation layer and the sixth insulation layer may be made of any one or more or any combination of silicon nitride (SiNx), silicon oxide (SiOx), silicon nitride oxide (SiON), and may be a single layer, multiple layers, or a composite layer. The fifth insulation layer and the seventh insulation layer may be made of an organic insulating material, for example, a resin material. The first to fourth conductive layers may be made of metal materials, for example, any one or more of aluminum (Al), molybdenum (Mo) and titanium (Ti), or alloys of the above metals, such as aluminum-neodymium (AlNd) or molybdenum-niobium (MoNb), and may be in a single-layer structure, or a multi-layer composite structure. However, the embodiment is not limited thereto.
(10) A light emitting structure layer is formed. In some examples, a bonding material (such as solder paste) is added into the first opening K1 to the sixth opening K6 using a glue dispenser, and connection between the light emitting element and the substrate is completed through a die bonding process. For example, the first electrode of the first light emitting element is bonded to the anode pad through the bonding material of the second opening K2, and the second electrode of the first light emitting element is bonded to the cathode pad through the bonding material in the first opening K1. Similarly, the bonding connection of the second light emitting element and the third light emitting element can be realized.

The structure of film layers in the transmissive region has not changed after this process.
(11) Forming a cover layer. In some examples, a cover thin film is coated on the substrate on which the aforementioned structures are formed, to form a cover layer. The cover layer may cover the repeating unit. After this process, the transmissive region may include: the substrate, and the first insulation layer to the sixth insulation layer provided sequentially on the substrate, and the cover layer. By providing the cover layer, the light emitting structure layer may be encapsulated and protected, and transmittance of the emitted light is not reduced.

In an exemplary implementation mode, the first insulation layer, the second insulation layer, the third insulation layer, the fourth insulation layer and the fifth insulation layer, the sixth insulation layer and the seventh insulation layer in a hollowed-out region A2-2 may be etched after the steps (3), (4), (5), (7) and (9) respectively, so that the first insulation layer, the second insulation layer, the third insulation layer, the fourth insulation layer and the fifth insulation layer, the sixth insulation layer and the seventh insulation layer form a hollowed-out structure in the hollowed-out region A2-2. Optionally, the first insulation layer 101 to the seventh insulation layer 107 located in the hollowed-out region A2-2 are etched at one time after step (9), so that the first insulation layer, the second insulation layer, the third insulation layer, the fourth insulation layer and the fifth insulation layer, the sixth insulation layer and the seventh insulation layer form a hollowed-out structure in the hollowed-out region A2-2.

In an exemplary implementation mode, the buffer layer b0 as shown in FIG. 5 may be formed on the substrate before step (1), the buffer layer b0 located in the hollowed-out region A2-2 may be etched after the buffer layer b0 is formed, or the buffer layer b0, the first insulation layer 101 to the seventh insulation layer 107 located in the hollowed-out region A2-2 may be etched at one time after step (9), so that the buffer layer b0, the first insulation layer, the second insulation layer, the third insulation layer, the fourth insulation layer and the fifth insulation layer, the sixth insulation layer and the seventh insulation layer form a hollowed-out structure in the hollowed-out region A2-2.

The structure of the transparent display panel of the exemplary embodiment and the manufacturing process thereof are described only as an example. In some exemplary implementation modes, a corresponding structure may be changed and a patterning process may be added or removed according to actual needs. For example, the data lines DL1 to DL2 and the initial signal line INIT may all be covered by the first power supply line VDD, or may all be covered by the second power supply line VSS. For another example, the first power supply line VDD may be located on the third conductive layer. For another example, the first power supply line VDD may cover the three data lines, and the second power supply line VDD may cover the initial signal line. For another example, the first power supply line VDD may cover the initial signal line, and the second power supply line VSS may cover the three data lines.

The manufacturing process of this exemplary embodiment may be implemented by using an existing mature manufacturing equipment, which has slight improvement on the existing processes, and can be well compatible with the existing manufacturing processes. The processes are easy to realize and implement, the production efficiency is high, the production cost is low, and the yield is high.

In this example, a plurality of first signal lines included in a set of first signal lines 11 within the repeating unit may include: a first power connection line 601, a second power connection line 602, a light emitting control line EML(n), a first scan line SL1(n), and a second scan line SL2(n). The light emitting control line EML(n), the first scan line SL1(n), and the second scan line SL2(n) may be electrically connected to pixel circuits of three sub-pixels within each pixel unit of a same row. A plurality of third signal lines included in a set of second signal lines 12 may include: data lines DL1 to DL3 and an initial signal line INIT, and a plurality of fourth signal lines included in the set of second signal lines may include: a first power supply line VDD and a second power supply line VSS. The orthographic projection of the first power supply line VDD on the substrate may cover the orthographic projection of the data lines DL1 and DL2 on the substrate, and the orthographic projection of the second power supply line VSS on the substrate may cover the orthographic projection of the data line DL3 and the initial signal line INIT on the substrate.

In some examples, line widths of the data lines may be determined based on data load and process preparation capability for metal wire, and line widths of the first power supply line VDD and the second power supply line VSS may be determined by a voltage drop and the process preparation capability for metal wire. In some examples, sizes (i.e., line widths) of data lines DL1 to DL3 and the initial signal line INIT in the first direction X may be approximately the same. A size of the first power supply line VDD in the first direction X may be greater than twice of a size of the data line DL1 in the first direction X. A size of the second power supply line VSS in the first direction X may be greater than twice the size of the data line DL1 in the first direction X. For example, an orthographic projection of two data lines DL1 on the substrate falls within an orthographic projection of one second power supply line VSS on the substrate, and a size of the second power supply line VSS in the first direction X is approximately equal to a sum of the sizes of the two data lines DL1 in the first direction X and a spacing between the two adjacent data lines DL1 in the first direction X.

In some examples, the spacing between adjacent data lines located in the third conductive layer or between a data line and an initial signal line adjacent to the data line may be about 3 microns, and the spacing between the first power supply line VDD and the second power supply line VSS located in the fourth conductive layer may be about 5 microns.

In this example, aggregation design is adopted for a plurality of first signal lines, and the aggregation design is adopted for a plurality of third signal lines and fourth signal lines, the first power supply line and the second power supply line are arranged to extend in the second direction Y, and a superimposition design may be adopted for the first power supply line and the second power supply line, and the data lines and the initial signal line extending in the second direction Y, which can achieve a largest area of a transmissive region of a minimum unit surrounded by the non-transmissive region, reduce diffraction and improve the display quality of the transparent display panel.

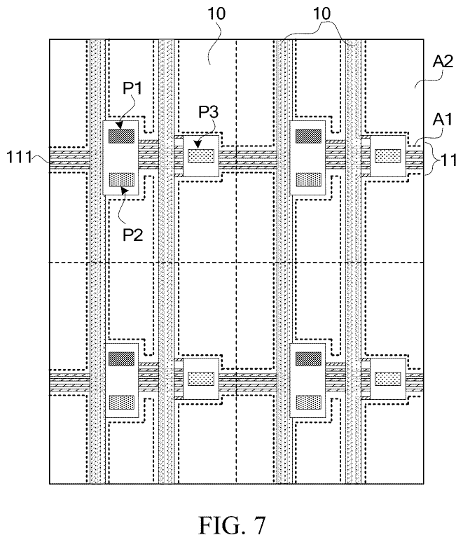

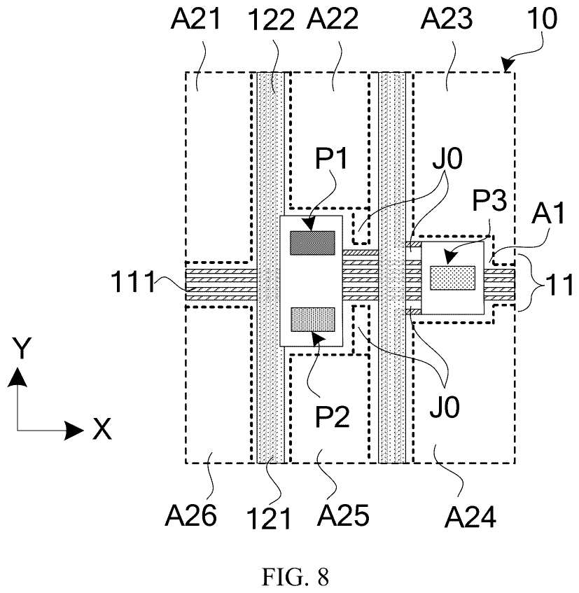

FIG. 7 is another schematic partial view of a transparent display panel according to at least one embodiment of the present disclosure. FIG. 8 is a schematic diagram of a repeating unit of a transparent display panel according to at least one embodiment of the present disclosure. FIG. 7 is formed by four repeating units as shown in FIG. 8 arranged in a 2×2 array.

In some examples, as shown in FIGS. 7 and 8, the repeating units 10 are substantially quadrilateral, and may be rectangular, for example. Transmissive sub-regions of the four repeating units 10 arranged in a 2×2 array may be interconnected to form a transmissive region A2. A transmissive region A2 may be surrounded by a non-transmissive region A1. The non-transmissive region A1 of the repeating unit 10 may include a pixel unit P, and a set of first traces 11 and two sets of second traces 12 electrically connected to the pixel unit P. A first sub-pixel P1, a second sub-pixel P2 and a third sub-pixel P3 of the pixel unit P may be arranged in a zigzag pattern, and the first sub-pixel P1 and the second sub-pixel P2 of the pixel unit P may be arranged sequentially along the second direction Y, and the third sub-pixel P3 and a small unit composed of the first sub-pixel P1 and the second sub-pixel P2 may be arranged sequentially along the first direction X. The set of first traces 11 may include a plurality of first signal lines 111 extending in the first direction X. The plurality of first signal lines 111 may include a scan line, a light emitting control line, a first power supply connection line and a second power supply connection line electrically connected to the pixel unit P. The two sets of second traces 12 may include a plurality of third signal lines 121 and a plurality of fourth signal lines 122 extending in the second direction Y. The plurality of fourth signal lines 122 and the plurality of third signal lines 121 may be located in different film layers. The plurality of third signal lines 121 may at least include three data lines and an initial signal line electrically connected to the pixel unit P. The plurality of fourth signal lines 122 may include a first power supply line and a second power supply line. For example, a fourth signal line 122, whose orthographic projection overlaps with an orthographic projection of the pixel unit P on the substrate, may be the second power supply line and another fourth signal line 122 may be the first power supply line. In some examples, the initial signal line may extend in the second direction Y, for example, belongs to the third signal line. In some examples, the first power supply line may be electrically connected to the first power supply connection line and the second power supply line may be electrically connected to the second power supply connection line, thereby realizing mesh transmission routes for the first voltage signal and the second voltage signal. As shown in FIG. 8, in the first direction X, a plurality of sub-pixels in a same pixel unit P are located at two sides of one of the fourth signal lines 122, and at least some of the sub-pixels are located between two fourth signal lines, for example, the first sub-pixel P1 and the second sub-pixel P2, and the third sub-pixel P3 are located at two sides of one of the fourth signal lines 122 (e.g., the first power supply line), and the first sub-pixel P1 and the second sub-pixel P2 are located between two fourth signal lines 122 (e.g., the first power supply line and the second power supply line).

In some examples, as shown in FIGS. 7 and 8, an orthographic projection of a fourth signal line 122 (e.g., the first power supply line) located in the fourth conductive layer on the substrate may cover an orthographic projection of a plurality of third signal lines (e.g., two signal lines) 121 located in the third conductive layer on the substrate. An orthographic projection of another fourth signal line 122 (e.g., the second power supply line) located in the fourth conductive layer on the substrate may cover an orthographic projection of another part of the third signal lines 121 (e.g., a data line and the initial signal line) on the substrate. A plurality of third signal lines 121 may be electrically connected to a plurality of pixel circuits of the pixel unit P via connection electrodes.

The transparent display panel provided by this example adopts an aggregation design for a plurality of first signal lines, an aggregation design for a plurality of third signal lines, and a superimposition design for one fourth signal line and a plurality of third signal lines, so that the area of a transmissive region of a minimum unit surrounded by the non-transmissive region can be maximized, thereby reducing diffraction and improving the display quality of the transparent display panel. The rest of the structure of the transparent display panel according to this embodiment may be referred to descriptions of the aforementioned embodiments, which will not be repeated here.

In an exemplary implementation mode, as shown in FIG. 8, at least one pixel unit P may include a plurality of sub-pixels, and the transmissive region A2 may include a spacing region J0 between a plurality of sub-pixels in a same pixel unit and between the sub-pixels and the first traces 11 or the second traces 12. In an exemplary implementation mode, the spacing region J0 may be provided in a hollowed-out structure to form a hollowed-out region in the transmissive region A2, thereby improving the sharpness of the display panel.

In an exemplary implementation mode, the buffer layer b0 may include a first buffer layer and a second buffer layer, and film layer parameters of the first buffer layer, the second buffer layer, the first insulation layer 101 to the seventh insulation layer 107 in the transition region A2-1 and the hollowed-out region A2-2 are shown in Table 1:

TABLE 1
Film Layer Parameters

| | | Thickness of | Thickness of |
|---|---|---|---|
| | | transition | hollowed-out |
| Film layer | Material | region (Å) | region (Å) |
| First buffer layer (buffer1) | SiNx/SiOx | 500/3000 | 0 |
| Second buffer layer (buffer2) | SiOx | 1200 | 0 |
| First insulation layer (GI1) | SiOx/SiNx | 800/400 | 0 |
| Second insulation layer (GI2) | SiNx | 1400 | 0 |
| Third insulation layer (ILD) | SiOx/SiNx | 2000/3000 | 0 |
| Fourth insulation layer (PVX1) | SiNx | 2000 | 0 |
| Fifth insulation layer (PVX2) | SiNx | 2000 | 0 |
| Seventh insulation layer (PLN) | Resin | 40000 | 0 |

Herein, the first buffer layer (buffer1) and the second buffer layer (buffer2) can be arranged between the substrate 100 and the first semiconductor layer in the direction perpendicular to the substrate, and can be collectively referred to as buffer layers for improving a water and oxygen resistance capability of the substrate. The first insulation layer (GI1) and the second insulation layer (GI2) may be referred to as gate insulating (GI) layers, the third insulation layer (ILD) may be referred to as an interlayer insulating (ILD) layer, the fourth insulation layer (PVX1) and the fifth insulation layer (PVX2) may be referred to as passivation (PVX) layers, and the seventh insulation layer (PLN) may be referred to as a planarization (PLN) layer. In an embodiment of the present disclosure, the first buffer layer, the second buffer layer, at least one of the first buffer layer to the seventh insulation layer located in the hollowed-out region may be provided in hollowed-out structures.

In an exemplary implementation mode, the transition region A2-1 may have a size of 0 microns to 10 microns in a direction from the non-transmissive region A1 to an adjacent hollowed-out region A2-2. For example, the size of the transition region A2-1 may be 8 microns in the direction from the non-transmissive region A1 to the adjacent hollowed-out region A2-2.

In an exemplary implementation mode, the transmittance of the transition region A2-1 is

$$\frac{b}{a} {E}_{0} {e}^{i ( kr - ( φ 1 - φ 2 ) )} ,$$

the transmittance of the hollowed-out region A2-2 is E₀e^{ikr}, a value of k is 2 π/λ, λ is a wave length of light wave, r is a size of the insulation layer located in the transition region A2-1 in the direction perpendicular to the substrate 100, E0 is an amplitude of light wave, φ1 is an optical delay of the transition region A2-1, φ2 is an optical delay of the hollowed-out region A2-2. i is an imaginary number, a is a first transmittance reference value (i.e., a transmittance reference value of the hollowed-out region A2-2), and b is a second transmittance reference value (i.e., a transmittance reference value of the transition region A2-1).

In an exemplary implementation mode, the optical delay φ1 of the transition region A2-1 is a product of a size and a refractive index of a film layer located in the transition region A2-1 in the direction perpendicular to the substrate 100.

In an exemplary implementation mode, the refractive index of the transition region A2-1 has a value range of 1.2 to 1.6, the value of r of the transition region A2-1 has a value range of 3 microns to 7 microns, and the wavelength of light has a value range of 500 nanometers to 560 nanometers.

In an exemplary implementation mode, the refractive index of the transition region A2-1 may be 1.4, the value of r of the transition region A2-1 may have a value range of 5 to 6 microns, and the wavelength of light may be 532 nanometers. Herein, r can be understood as an optical path of light wave in the insulation layer.

In an exemplary implementation mode, the refractive index of the hollowed-out region A2-2 may be 1, i.e., the refractive index of air. The value of r of the hollowed-out region A2-2 can be 0 micron, that is, all the insulation layers of the hollowed-out region A2-2 are provided in hollowed-out structures. In an exemplary implementation mode, the optical delay φ2 of the hollowed-out region A2-2 may be 0 and since the value of r is 0, the value of the refractive index n of the hollowed-out region is 1, therefore,

$$\frac{b}{a} {E}_{0} {e}^{i ( kr - ( φ 1 - φ 2 ) )}$$

can be simplified to

$$\frac{b}{a} {E}_{0} {e}^{ikrn} .$$

In an exemplary implementation mode, the hollowed-out region A2-2 may include the substrate 100 and the cover layer 23 arranged sequentially in the second direction Y.

In an exemplary implementation mode, the transmittance of the non-transmissive region A1 may be 0, i.e., the non-transmissive region A1 is opaque.

In an exemplary implementation mode, a wavelength of light wave may be the wavelength reflected from an object behind the transparent display screen. Due to the small thickness of PVX1/PVX2/ILD, its product with the refractive index n (around 1.4) is too small compared to the wavelength (e.g., 532 nm) and can be negligible, and the refractive index in the embodiment of the present disclosure may be referred to primarily as the refractive index of the PLN.

In an exemplary implementation mode, factors affecting a picture quality of the transparent display panel generally include diffraction intensity, transmittance of light at different positions of pixels, and phase distribution correlation, which can be calculated by modularization after Fourier transform. Herein, the diffraction intensity refers to the magnitude of the light intensity of each diffraction spot.

The transmittance of light at different positions in the display panel may include metal wires in the conductive layer and a shielding structure (i.e., the non-transmissive region A1) and the transmissive region A2, which are, for example, related to the width, spacing and arrangement of the metal wires and the shielding structure (BM) in the non-transmissive region A1.

The influence on the picture quality in the transmissive region A2 can be categorized into the following two cases:

In a first case, optical characteristics of the entire transmissive region A2 are consistent (such as refractive index and light absorption rate of insulation layers), that is, all insulation layers in the transmissive region A2 are provided in hollowed-out structures, and the width of the transition region A2-1 is 0 (that is, the transmissive region A2 is provided as the hollowed-out region A2-2), which is not related to the phase and amplitude of the light wave, but is only related to the non-transmissive region A1 (the line width and spacing of metal wires/BM in the non-transmissive region A1, etc.) (all is hollowed in the patent (as shown in Table 2 below, the diffraction intensity is 2.4% in the second direction Y direction and 7.2% in the first direction X direction, respectively).

In a second case, if the optical characteristics of the transmissive region A2 are inconsistent (the transmissive region A2 includes the transition region A2-1 and the hollowed-out region A2-2), there are a difference in transmittance and a difference in phase (such as the thickness of the film layer and the refractive index of the insulation layer) and regional distribution that is relevant, between the transition region A2-1 and the hollowed-out region A2-2.

A method for evaluating the picture quality of the transparent display panel can adopt the algorithm in related technology (Algorithms for Evaluating the Quality of Multiscale Images, reference: IEEE TRANSACTIONS ON IMAGE PROCESSING, VOL. 21, NO. 12, December 2012) and it is approximately inversely proportional to diffraction intensity (under the condition of constant diffraction angle, etc.).

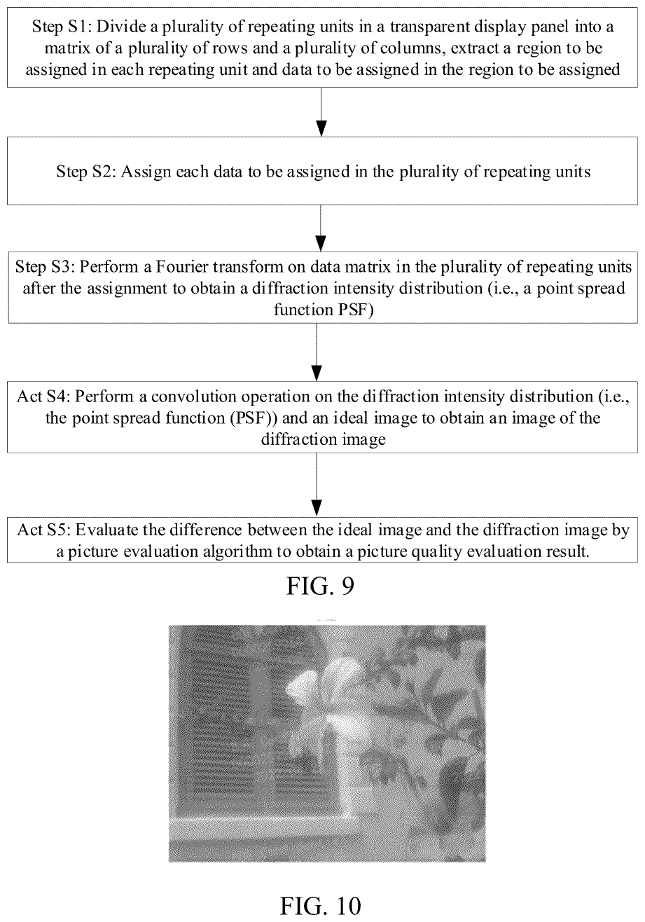

As shown in FIG. 9, the method for evaluating the picture quality of the transparent display panel may include following operations.

Step S1: Dividing a plurality of repeating units in the transparent display panel into a matrix of a plurality of rows and a plurality of columns, extracting a region to be assigned in each repeating unit and data to be assigned in the region to be assigned.

As shown in FIG. 8, the region to be assigned in each repeating unit may include data to be assigned in three regions: the non-transmissive region A1, the transition region A2-1 and the hollowed-out region A2-2.

Step S2: Assigning each data to be assigned in the plurality of repeating units.

For example, the data to be assigned in the non-transmissive region A1 is set to 0. The data to be assigned in the transition region A2-1 is mainly to assign

$$\frac{b}{a} {E}_{0} {e}^{ikrn} .$$

The values of a, b, k, r and n in the transition region A2-1 can be obtained and brought into

$$\frac{b}{a} {E}_{0} {e}^{ikrn}$$

to complete the assignment of the transition region A2-1. Assuming that the value of b/a is 0.8 and the value of E₀ is set to 1, the obtained transmittance formula is 0.8e^{ikrn}, the value of k is 2 π/λ, that is, the wavelength λ of light wave corresponding to the transition region A2-1, the thickness r of the insulation layer and the refractive index n of the insulation layer can be obtained and brought into 0.8e^{ikrn} to complete the assignment of the data of the transition region A2-1. The data to be assigned in the hollowed-out region A2-2 is mainly to assign the data in E₀e^{ikr}, the value of k is 2 π/λ, and the value of E₀ is set to 1, that is, the wavelength λ of light wave corresponding to the hollowed-out region A2-2 and the thickness r of the insulation layer can obtained and brought into e^{ikr} to complete the assignment of the data of the hollowed-out region A2-2.

Step S3: Performing a Fourier transform on a data matrix in the plurality of repeating units after the assignment to obtain a diffraction intensity distribution (i.e., a point spread function PSF).

Step S4: Performing a convolution operation on the diffraction intensity distribution (i.e., the point spread function (PSF)) and an ideal image to obtain an image of the diffraction image.

Step S5: Evaluating a difference between the ideal image and the diffraction image by a picture evaluation algorithm to obtain a picture quality evaluation result.

The picture evaluation algorithm in step S5 can use the algorithm in related technology (Algorithms for Evaluating the Quality of Multiscale Images, reference: IEEE TRANSACTIONS ON IMAGE PROCESSING, VOL. 21, NO. 12, December 2012). A scoring result can be obtained by evaluating the difference between the ideal image and the diffraction image by the picture evaluation algorithm, as shown in Table 2:

TABLE 2

| | | Width of transition region A2-1 | | |
|---|---|---|---|---|
| Evaluation parameter | | 18 microns | 8 microns | 0 micron |
| Diffraction | Second direction Y | 7 | 5.7 | 2.4 |
| intensity | First Direction X | 20 | 12.2 | 7.2 |

| | | | |
|---|---|---|---|
| Image quality | 0.76 | 0.92 | 1 |

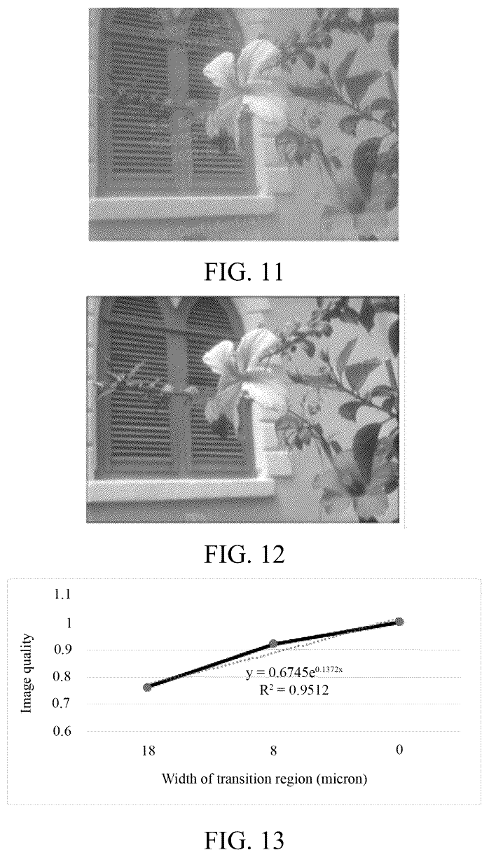

FIG. 10 is an example diagram of a display effect of a picture in which the width of the transition region A2-1 is 18 microns, FIG. 11 is an example diagram of a display effect of a picture in which the width of the transition region A2-1 is 8 microns, and FIG. 12 is an example diagram of a display effect of a picture in which the width of the transition region A2-1 is 0 microns. It can be seen from FIG. 10 to FIG. 12 that the smaller the width of the transition region A2-1 (that is, the size of the transition region in a direction from the non-transmissive region to an adjacent hollowed-out region), the better the picture quality. However, since it is difficult in the process to set the size of the width of the transition region A2-1 to 0 microns, the width of the transition region A2-1 can generally be set between 0 microns and 8 microns. As shown in Table 2, when the width of transition region A2-1 is 8 microns, the image quality is 0.92, which is much higher than the image quality of 0.76 for the transition region A2-1 with a width of 18 microns.

The image quality in Table 2 is an evaluation result of the picture quality.

As shown in FIG. 13, which is a schematic diagram of a relationship between the width of the transition region A2-1 and the image quality (i.e., the picture quality), the relationship between the picture quality and the width of the transition region A2-1 (i.e., the size of the transition region along a direction from the non-transmissive region to the adjacent hollowed-out region) is y=0.6745e^{0.1372x}, R²=0.9512, where Y represents the image quality, and the image quality refers to people's subjective evaluation of the visual perception of an image. The image quality here is between 0 and 1, and the closer it is to 1, the better the image quality is. X represents the width of the transition region A2-1 in microns (μm). R² represents the linear regression coefficient, which is between 0 and 1, the closer it is to 1, the better the effect of the regression fitting. It is generally considered that a model fitting goodness exceeding 0.8 is relatively high.

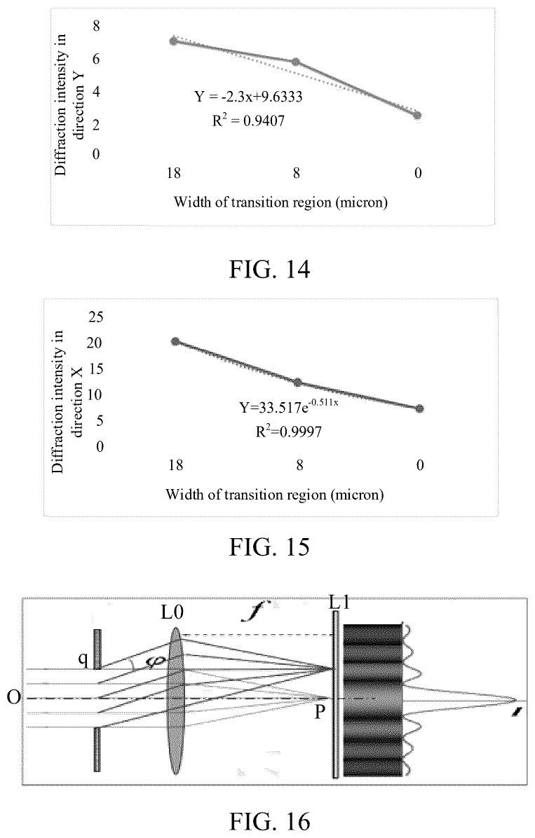

FIG. 14 shows a relationship between the diffraction intensity in the second direction Y and the width of the transition region A2-1: y=−2.3x+9.6333, R²=0.9407, where Y represents the diffraction intensity in the second direction Y, in CPS (Counts Per Second). X represents the width of the transition region A2-1 in microns (μm). R² represents a linear regression coefficient, which is between 0 and 1, the closer it is to 1, the better the effect of the regression fitting. It is generally considered that a model fitting goodness exceeding 0.8 is relatively high.

As shown in FIG. 15, the relationship 2 between the diffraction intensity in the first direction and the width of the transition region A2-1 is: y=33.517e^{-0.511x}, R²=0.9997, where Y represents the diffraction intensity in the first direction X, in CPS. X represents a width of step coverage, in microns (μm). R² represents a linear regression coefficient, which is between 0 and 1, the closer it is to 1, the better the effect of the regression fitting. It is generally considered that a model fitting goodness exceeding 0.8 is relatively high.

Due to its fluctuating nature, light diffracts after passing through a slit or an aperture, changing its original direction of propagation. As shown in FIG. 16, which is a schematic diagram of diffraction of light after passing through an aperture or slit, in FIG. 16, I is light intensity of diffracted spot, in CPS, q is an aperture or slit, L0 is a lens, L1 is an observation screen, OP is an optical axis, φ is a diffraction angle, i.e., an angle between the light after passing through the aperture or slit and the optical axis OP, and f is a distance between the lens and the observation screen L1. In an embodiment of the present disclosure, the insulation layers of the transmissive region A2 are equated with the lens L0 in FIG. 16, a position where the user views the transparent display screen is equated with the observation screen L1, and the size of the hollowed-out region A2-2 is equated with the slit or aperture q in FIG. 16.

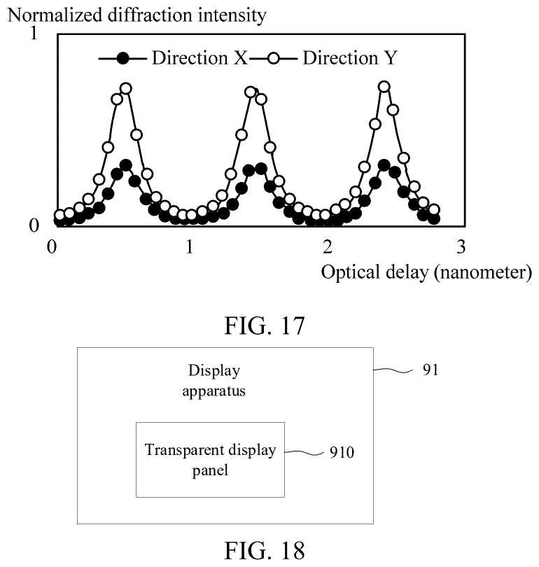

As shown in FIG. 17, which is a schematic diagram of a relationship between an optical delay and a diffraction intensity, wherein the optical delay can be a product of a thickness of a insulation layer and a refractive index of the insulation layer in the transmissive region A2, in nanometers. In FIG. 17, the ordinate is the normalized diffraction intensity, and the diffraction intensity may be a first-order diffraction intensity, which is, for example, the intensity of a first diffraction peak of a repeating unit. X in FIG. 17 is the first direction X in FIG. 8, and Y in FIG. 17 is the second direction Y in FIG. 8.

In the transparent display panel according to an embodiment of the present disclosure, the width of the transition region A2-1 is reduced from 18 microns to 8 microns, and the picture quality can be improved from 0.76 to 0.92. On the premise of further reducing the width of the transition region A2-1 and ensuring reliability (a condition of reliability guarantee can be that operation time is more than or equal to 500 hours under at least one environment of high temperature, low temperature and high temperature and high humidity, for example, the operation time is all greater than or equal to 500 hours under HTO: high temperature operation, LTO: low temperature operation and THO: high temperature and high humidity operation), the picture quality can be further improved. For example, a temperature for high temperature operation is about 60° C. (for example, 50° C. to 70° C.), a temperature for low temperature operation is about −5° C. (for example, −15° C. to 5° C.), a temperature for high temperature and high humidity operation is about 60° C. (for example, 50° C. to 70° C.), and a humidity is about 80% (for example, 70% to 90%).

FIG. 18 is a schematic diagram of a display apparatus according to at least one embodiment of the present disclosure. As shown in FIG. 18, this embodiment provides a display apparatus 91, which includes a transparent display panel 910. The transparent display panel 910 may be a micro-LED display panel or a mini-LED display panel. The display apparatus 91 may be: a car window glass, a mall cabinet, an augmented reality (AR, Augmented Reality) device, a virtual reality (VR, Virtual Reality) device, and any other products or components with the transparent display function. However, the embodiment is not limited thereto.

The drawings of the present disclosure only involve structures involved in the present disclosure, and other structures may refer to conventional designs. The embodiments of the present disclosure and features in the embodiments may be combined to each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A transparent display panel comprising:
a substrate;
a plurality of repeating units arranged in an array on the substrate, wherein a repeating unit comprises a non-transmissive region and a plurality of transmissive regions, adjacent transmissive regions are spaced apart by the non-transmissive region;
a transmissive region comprises a hollowed-out region and a transition region, wherein the transition region is located between the non-transmissive region and the hollowed-out region, and at least one insulation layer in the hollowed-out region is provided in a hollowed-out structure; and
the non-transmissive region comprises at least one pixel unit and N sets of first traces extending in a first direction and M sets of second traces extending in a second direction electrically connected to the at least one pixel unit, the first direction and the second direction intersect, and both N and M are positive integers.

2. The transparent display panel according to claim 1, wherein the transition region has a size of 0 microns to 10 microns in a direction from the non-transmissive region to an adjacent hollowed-out region.

3. The transparent display panel according to claim 2, wherein the transition region has a size of 8 microns in the direction from the non-transmissive region to the adjacent hollowed-out region.

4. The transparent display panel according to claim 1, wherein the transparent display panel comprises at least one conductive layer and at least one insulation layer disposed on the substrate, and one or more insulation layers located in the hollowed-out region are provided in hollowed-out structures.

5. The transparent display panel according to claim 4, further comprising a semiconductor layer disposed on the substrate, the conductive layer comprises a first conductive layer to a fourth conductive layer, and the at least one insulation layer comprises a first insulation layer to a seventh insulation layer;
in a direction perpendicular to the substrate, the first conductive layer to the fourth conductive layer are sequentially arranged on a side of the semiconductor layer away from the substrate, the first insulation layer is located between the semiconductor layer and the first conductive layer, a second insulation layer is located between the first conductive layer and a second conductive layer, a third insulation layer is located between the second conductive layer and a third conductive layer, a fourth insulation layer and a fifth insulation layer are located between the third conductive layer and the fourth conductive layer, and a sixth insulation layer and the seventh insulation layer are sequentially arranged on a side of the fourth conductive layer away from the substrate; and
at least one of the first insulation layer to the seventh insulation layer located in the hollowed-out region is provided in a hollowed-out structure.

6. The transparent display panel according to claim 5, wherein a buffer layer is further provided between the substrate and the semiconductor layer in the direction perpendicular to the substrate, and the buffer layer located in the hollowed-out region may be provided in a hollowed-out structure.

7. The transparent display panel according to claim 5, wherein a transmittance of the transition region is
$$\frac{b}{a} {E}_{0} {e}^{i ( kr - ( φ 1 - φ 2 ) )} ,$$
a transmittance of hollowed-out region is E₀e^{ikr}, a value of k is 2 π/λ, λ is a wave length of light wave, r is a size of the insulation layer located in the transition region in the direction perpendicular to the substrate, E0 is an amplitude of light wave, φ1 is an optical delay of the transition region, φ2 is the optical delay of the hollowed-out region, a is a first transmittance reference value, and b is a second transmittance reference value.

8. The transparent display panel according to claim 7, wherein the optical delay φ1 of the transition region is a product of a size and a refractive index of a film layer located in the transition region in the direction perpendicular to the substrate.

9. The transparent display panel according to claim 8, wherein a refractive index of the transition region has a value range of 1.2 to 1.6, a value of r of the transition region has a value range of 3 microns to 7 microns, and a wavelength of light has a value range of 500 nanometers to 560 nanometers; or
wherein a refractive index of the hollowed-out region is 1 and a value of r of the hollowed-out region is 0 micron.

10. The transparent display panel according to claim 9, wherein the refractive index of the transition region is 1.4, the value of r of the transition region has a value range of 5 to 6 microns, and the wavelength of light is 532 nanometers.

11. (canceled)

12. The transparent display panel according to claim 7, wherein a transmittance of the non-transmissive region is 0.

13. The transparent display panel according to claim 1, wherein at least one set of first traces comprises: a plurality of first signal lines; at least one set of second traces comprises a plurality of third signal lines and at least one fourth signal line, an orthographic projection of the at least one fourth signal line on the substrate covers an orthographic projection of at least two third signal lines on the substrate.

14. The transparent display panel according to claim 13, wherein a size of the at least one fourth signal line in the first direction is larger than a size of the at least two third signal lines in the first direction.

15. The transparent display panel according to claim 13, wherein N and M are both 1, a set of first traces comprises a plurality of first signal lines, and a set of second traces comprises a plurality of third signal lines and at least one fourth signal line; the at least one fourth signal line comprises a first power supply line and a second power supply line; an orthographic projection of at least one of the first power supply line and the second power supply line on the substrate covers an orthographic projection of the plurality of third signal lines on the substrate.

16. The transparent display panel according to claim 13, wherein N is 1 and M is 2, a set of first traces comprises a plurality of first signal lines, two sets of second traces comprise a plurality of third signal lines and at least two fourth signal lines, and one set of second traces comprises some of the third signal lines and at least one of the fourth signal lines; the at least two fourth signal lines comprise a first power supply line and a second power supply line; an orthographic projection of at least one of the first power supply line and the second power supply line on the substrate covers an orthographic projection of the plurality of third signal lines on the substrate.

17. The transparent display panel according to claim 16, wherein the at least one pixel unit comprises: a plurality of sub-pixels emitting light of different colors, a plurality of sub-pixels in a same pixel unit are located at two sides of one of the fourth signal lines in the first direction, and at least some of the sub-pixels are located between two fourth signal lines.

18. The transparent display panel according to claim 15, wherein the plurality of first signal lines of the set of first traces comprise a scan line, a light emitting control line, a first power connection line, and a second power connection line, the first power connection line is electrically connected to the first power supply line, and the second power connection line is electrically connected to the second power supply line.

19. The transparent display panel according to claim 15, wherein the plurality of third signal lines comprises at least a plurality of data lines electrically connected to the at least one pixel unit.

20. The transparent display panel according to claim 15,
wherein the at least one pixel unit comprises a plurality of sub-pixels, and
the transmissive region comprises a spacing region between the plurality of sub-pixels and between the sub-pixels and the first trace or the second trace in a same pixel unit.

21. A display apparatus, comprising the transparent display panel according to claim 1.
